(19) United States
(12) Patent Application Publication
(10) Pub. No.: US 2025/0171683 A1
(43) Pub. Date: May 29, 2025

(54) EMISSION MATERIAL, AND ORGANIC ELECTROLUMINESCENT DEVICE

(71) Applicants: NIPPON STEEL Chemical & Material Co., Ltd., Tokyo (JP); KYUSHU UNIVERSITY, NATIONAL UNIVERSITY CORPORATION, Fukuoka (JP)

(72) Inventors: Masashi TADA, Tokyo (JP); Yuta SAGARA, Tokyo (JP); Sayuri KITERA, Tokyo (JP); Takuma YASUDA, Fukuoka (JP); Hyukgi MIN, Fukuoka (JP)

(73) Assignees: NIPPON STEEL Chemical & Material Co., Ltd., Tokyo (JP); KYUSHU UNIVERSITY, NATIONAL UNIVERSITY CORPORATION, Fukuoka (JP)

(21) Appl. No.: 18/836,342

(22) PCT Filed: Jan. 30, 2023
(86) PCT No.: PCT/JP2023/002947

§ 371 Date: Aug. 6, 2024

(30) Foreign Application Priority Data
Feb. 17, 2022 (JP) 2022-022671

(51) Int. Cl. C09K 11/06; H10K 50/12; H10K 85/40; H10K 85/60; H10K 101/00; H10K 101/10

(52) U.S. Cl. CPC C09K 11/06; H10K 50/12; H10K 85/40; H10K 85/622; H10K 85/633; H10K 85/636; H10K 85/654; H10K 85/6572; H10K 85/6574; H10K 85/6576; H10K 85/658; C09K 2211/1022; H10K 2101/10; H10K 2101/90

(57) ABSTRACT

Provided are an emission material and an organic EL device including the emission material and having high emission efficiency and a long lifetime. An organic EL device comprising light emitting layers between an anode and a cathode opposite to each other; wherein at least one of the light emitting layers contains, as a light emitting dopant, a compound in which a backbone having a specific structure and a boron atom are combined, and the compound is represented by the following general formula (1) or the general formula (2).

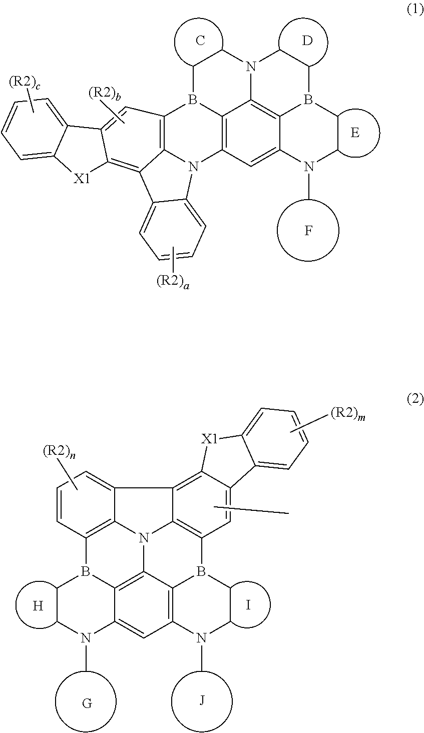

### TECHNICAL FIELD

The present invention relates to an emission material and an organic electroluminescent device (also referred to as an organic EL device) including the emission material as a light emitting layer.

When a voltage is applied to an organic EL device, holes and electrons are injected from the anode and the cathode, respectively, into the light emitting layer. Then, the injected holes and electrons are recombined in the light emitting layer to thereby generate excitons. At this time, according to the electron spin statistics theory, singlet excitons and triplet excitons are generated at a ratio of 1:3. In the fluorescent organic EL device that uses emission caused by singlet excitons, the limit of the internal quantum efficiency is said to be 25%. On the other hand, it has been known that, in the phosphorescent organic EL device that uses emission caused by triplet excitons, the internal quantum efficiency can be enhanced up to 100% when intersystem crossing efficiently occurs from singlet excitons.

A technology for extending the lifetime of a phosphorescent organic EL device has advanced in recent years, and the device is being applied to a display of a mobile phone and others. Regarding a blue organic EL device, however, a practical phosphorescent organic EL device has not been developed, and thus the development of a blue organic EL device having high efficiency and a long lifetime is desired.

Further, a highly efficient delayed fluorescence organic EL device utilizing delayed fluorescence has been developed, in recent years. For example, Patent Literature 1 discloses an organic EL device utilizing the Triplet-Triplet Fusion (TTF) mechanism, which is one of the mechanisms of delayed fluorescence. The TTF mechanism utilizes a phenomenon in which a singlet exciton is generated by the collision of two triplet excitons, and it is believed that the internal quantum efficiency can be enhanced up to 40%, in theory. However, its efficiency is low as compared with the efficiency of the phosphorescent organic EL device, and thus further improvement in efficiency is desired.

On the other hand, Patent Literature 2 discloses an organic EL device utilizing the Thermally Activated Delayed Fluorescence (TADF) mechanism. The TADF mechanism utilizes a phenomenon in which reverse intersystem crossing occurs from the triplet exciton to the singlet exciton in a material having a small energy difference between the singlet level and the triplet level, and it is believed that the internal quantum efficiency can be enhanced up to 100%, in theory. Specifically, Patent Literature 2 discloses an indolocarbazole compound as a thermally activated delayed fluorescence material.

Patent Literature 3, Patent Literature 4, and Patent Literature 5 each disclose an emission material including a polycyclic aromatic compound containing a boron atom, and an organic EL device including the emission material.

### CITATION LIST

### Patent Literature

Patent Literature 1: WO2010/134350
Patent Literature 2: WO2011/070963
Patent Literature 3: WO2015/102118
Patent Literature 4: WO2019/240080
Patent Literature 5: WO2021/008374

### SUMMARY OF INVENTION

### Technical Problem

In view of applying an organic EL device to a display device such as a flat panel display and a light source, it is necessary to improve the emission efficiency of the device and sufficiently ensure the stability of the device at the time of driving, at the same time. The present invention has been made under such circumstances, and an object thereof is to provide an emission material that can be used to obtain a practically useful organic EL device having high emission efficiency and high driving stability, and an organic EL device including the emission material.

### Solution to Problem

The present invention relates to an emission material represented by the following general formula (1) or general formula (2), and also to an organic EL device comprising one or more light emitting layers between an anode and a cathode opposite to each other, wherein at least one of the light emitting layers contains the emission material.

Specifically, the present invention is an emission material represented by the following general formula (1) or general formula (2).

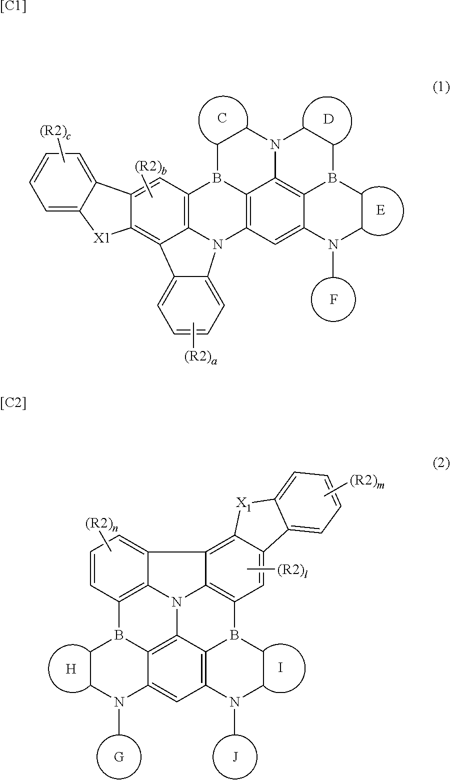

In the formulas, a ring C, a ring D, a ring E, a ring H, and a ring I each independently represent a substituted or unsubstituted aromatic hydrocarbon ring having 6 to 24 carbon atoms, or a substituted or unsubstituted aromatic heterocyclic ring having 3 to 18 carbon atoms, and
a ring F, a ring G, and a ring J each independently represent a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings.

A hydrogen atom in the general formulas (1) and (2) is optionally replaced with a deuterium atom, and each X1 independently represents N—R1, O, or S, wherein R1 represents a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings.

Each R2 independently represents an aliphatic hydrocarbon group having 1 to 6 carbon atoms, a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings. a, b, c, l, m, and n each represent the number of substitutions, a, c, and m each independently represent an integer of 0 to 4, n represents an integer of 0 to 3, and b and 1 each independently represent an integer of 0 to 1. Although the terms aromatic hydrocarbon ring and aromatic hydrocarbon ring group are both used herein, there is no substantial difference between them. The same is applied to the terms aromatic heterocyclic ring and aromatic heterocyclic group.

Each pair of a pair of the ring C and the ring D and a pair of the ring E and the ring F in the general formula (1) optionally together forms a ring via a direct bond or a linking group. Each pair of a pair of the ring H and the ring G and a pair of the ring I and the ring J in the general formula (2) optionally together forms a ring via a direct bond or a linking group.

The general formula (1) is preferably represented by the following general formula (3), and the general formula (2) is preferably represented by the following general formula (4).

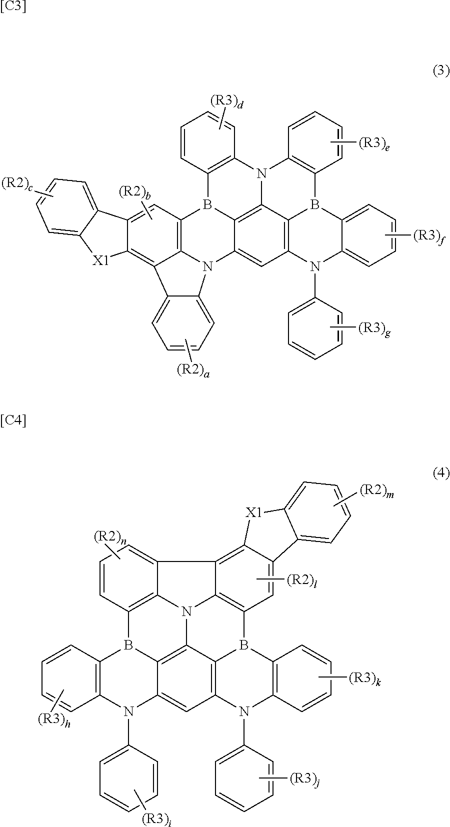

In the formulas, X1, R2, a, c, m, n, b, and I have the same meanings as described for the general formula (1) or (2). Each R3 independently represents an aliphatic hydrocarbon group having 1 to 6 carbon atoms, a substituted or unsubstituted aromatic hydrocarbon ring group having 6 to 24 carbon atoms, or a substituted or unsubstituted aromatic heterocyclic group having 3 to 18 carbon atoms. d, e, f, g, h, i, j, and k each represent the number of substitutions, g, i, and j each independently represent an integer of 0 to 5, and d, e, f, h, and k each independently represent an integer of 0 to 4.

The present invention is an organic electroluminescent device comprising one or more light emitting layers between an anode and a cathode opposite to each other, wherein at least one of the light emitting layers contains the above emission material.

In the organic electroluminescent device of the present invention, at least one light emitting layer containing the emission material preferably contains a first host selected from compounds represented by following general formula (5) and a second host selected from compounds represented by the following general formula (6).

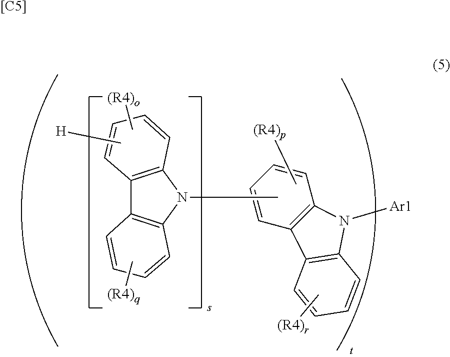

In the formula, Ar1 represents a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings. Each R4 independently represents an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms. o, p, q, and r each represent the number of substitutions, q and r each independently represent an integer of 0 to 4, and o and p each independently represent an integer of 0 to 3. s represents the number of repetitions and an integer of 1 to 4, and t represents the number of substitutions and an integer of 1 or 2. A hydrogen atom in the general formula (5) is optionally replaced with a deuterium atom. If t is 2, the general formula (5) may be symmetrical or asymmetrical.

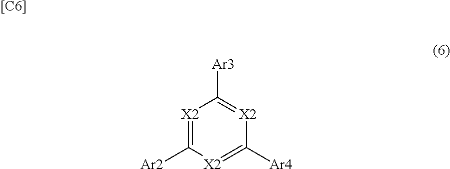

In the formula, each X2 independently represents N or C—R5, provided that at least one X2 represents N. Ar2, Ar3, and Ar4 each independently represent a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings. Each R5 independently represents hydrogen, deuterium, an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms. A hydrogen atom in the general formula (6) is optionally replaced with a deuterium atom.

In the organic electroluminescent device of the present invention, the emission material represented by the above general formula (1) or (2) preferably has a difference between the excited singlet energy (S1) determined by measuring the emission spectrum and the excited triplet energy (T1) determined by measuring the phosphorescence spectrum (ΔEST, that is, ΔEST for found values), of 0.20 eV or less.

The organic electroluminescent device of the present invention preferably includes a light emitting layer containing 0.1 to 10 wt % of the emission material represented by the general formula (1) or (2) as a dopant, and 99.9 to 90 wt % of the above first host represented by the general formula (5) and second host represented by the general formula (6) in total.

### Advantageous Effect of Invention

A practically useful organic EL device having high emission efficiency and high driving stability can be obtained by the emission material of the present invention.

### BRIEF DESCRIPTION OF DRAWING

FIG. 1 shows a schematic cross-sectional view of a structure example of the organic EL device used in the present invention.

### DESCRIPTION OF EMBODIMENTS

The organic EL device of the present invention has one or more light emitting layers between an anode and a cathode opposite to each other, and at least one layer of the light emitting layers contains the emission material represented by the general formula (1) or the general formula (2). The organic EL device preferably has one or more light emitting layers between an anode and a cathode opposite to each other, and at least one layer of the light emitting layers contains the emission material represented by the general formula (3) or the general formula (4). Of the emission materials represented by the general formula (1) and the general formula (2), the emission material represented by the general formula (2) is preferred. Of the emission materials represented by the general formula (3) and the general formula (4), the emission material represented by the general formula (4) is preferred. While the organic EL device has a plurality of layers between an anode and a cathode opposite to each other, at least one layer of the plurality of layers is a light emitting layer, and the light emitting layer contains a first host selected from compounds represented by the general formula (5) and a second host selected from compounds represented by the general formula (6), as necessary.

The general formula (1), the general formula (2), the general formula (3), and the general formula (4) will be described below.

B in the general formula (1), the general formula (2), the general formula (3), and the general formula (4) represents a boron atom.

A ring C, a ring D, a ring E, a ring H, and a ring I in the general formula (1) or the general formula (2) each independently represent a substituted or unsubstituted aromatic hydrocarbon ring having 6 to 24 carbon atoms, or a substituted or unsubstituted aromatic heterocyclic ring having 3 to 18 carbon atoms. Preferably, the ring C, the ring D, the ring E, the ring H, and the ring I each independently represent a substituted or unsubstituted benzene ring, or a substituted or unsubstituted aromatic heterocyclic ring having 3 to 18 carbon atoms. More preferably, the ring C, the ring D, the ring E, the ring H, and the ring I each independently represent a substituted or unsubstituted benzene ring, or a substituted or unsubstituted aromatic heterocyclic ring having 3 to 12 carbon atoms.

Specific examples of the unsubstituted aromatic hydrocarbon ring and the unsubstituted aromatic heterocyclic ring for the ring C, the ring D, the ring E, the ring H, and the ring I in the general formula (1) or the general formula (2) include benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, and carbazole. Preferred examples thereof include benzene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole. More preferred examples thereof include benzene, pyridine, pyrimidine, pyrazine, quinoline, isoquinoline, quinoxaline, quinazoline, indole, benzofuran, dibenzofuran, dibenzothiophene, carbazole.

The ring F, the ring G, and the ring J in the general formula (1) or the general formula (2) each independently represent a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings. Preferably, the ring F, the ring G, and the ring J each independently represent a substituted or unsubstituted benzene ring group, a substituted or unsubstituted aromatic heterocyclic group having 3 to 18 carbon atoms, or a substituted or unsubstituted linked aromatic group formed by linking 2 to 8 these aromatic rings. More preferably, the ring F, the ring G, and the ring J each independently represent a substituted or unsubstituted benzene ring group, a substituted or unsubstituted aromatic heterocyclic group having 3 to 12 carbon atoms, or a substituted or unsubstituted linked aromatic group formed by linking 2 to 8 these aromatic rings.

Specific examples of the unsubstituted aromatic hydrocarbon ring group, the unsubstituted aromatic heterocyclic group, and the unsubstituted linked aromatic group for the ring F, the ring G, and the ring J in the general formula (1) or the general formula (2) include benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole, and a group produced by removing one hydrogen atom from a compound formed by linking 2 to 8 these aromatic rings. Preferred examples thereof include benzene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole, and a group produced by removing one hydrogen atom from a compound formed by linking 2 to 8 these aromatic rings. More preferred examples thereof include benzene, pyridine, pyrimidine, pyrazine, quinoline, isoquinoline, quinoxaline, quinazoline, indole, benzofuran, dibenzofuran, dibenzothiophene, carbazole, and a group produced by removing one hydrogen atom from a compound formed by linking 2 to 8 these aromatic rings.

A hydrogen atom in the general formula (1) or the general formula (2) is optionally replaced with a deuterium atom.

Each X1 in the general formula (1) or the general formula (2) independently represents N—R1, O, or S. Preferably, each X1 independently represents N—R1 or O.

R1 in the general formula (1) or the general formula (2) represents a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings. R1 preferably represents a substituted or unsubstituted benzene ring group, a substituted or unsubstituted aromatic heterocyclic group having 3 to 18 carbon atoms, or a substituted or unsubstituted linked aromatic group formed by linking 2 to 8 these aromatic rings. R1 more preferably represents a substituted or unsubstituted benzene ring group, a substituted or unsubstituted aromatic heterocyclic group having 3 to 12 carbon atoms, or a substituted or unsubstituted linked aromatic group formed by linking 2 to 8 these aromatic rings.

Specific examples of the unsubstituted aromatic hydrocarbon ring group, the unsubstituted aromatic heterocyclic group, and the unsubstituted linked aromatic group for R1 in the general formula (1) or the general formula (2) are the same as those shown above for the ring F, the ring G, and the ring J. Preferred examples thereof include benzene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole, and a group produced by removing one hydrogen atom from a compound formed by linking 2 to 8 these aromatic rings. More preferred examples thereof include benzene, pyridine, pyrimidine, pyrazine, quinoline, isoquinoline, quinoxaline, quinazoline, indole, benzofuran, dibenzofuran, dibenzothiophene, carbazole, and a group produced by removing one hydrogen atom from a compound formed by linking 2 to 8 these aromatic rings.

Each R2 in the general formula (1) or the general formula (2) independently represents an aliphatic hydrocarbon group having 1 to 6 carbon atoms, a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings. Preferably, each R2 independently represents an aliphatic hydrocarbon group having 1 to 6 carbon atoms, a substituted or unsubstituted benzene ring, a substituted or unsubstituted aromatic heterocyclic ring having 3 to 18 carbon atoms, or a substituted or unsubstituted linked aromatic group formed by linking 2 to 8 these aromatic rings. More preferably, each R2 independently represents an aliphatic hydrocarbon group having 1 to 6 carbon atoms, a substituted or unsubstituted benzene ring, a substituted or unsubstituted aromatic heterocyclic ring having 3 to 12 carbon atoms, or a substituted or unsubstituted linked aromatic group formed by linking 2 to 8 these aromatic rings.

Specific examples of the aliphatic hydrocarbon group for R2 in the general formula (1) or the general formula (2) include a methyl group, an ethyl group, an n-propyl group, an isopropyl group, an n-butyl group, an isobutyl group, an s-butyl group, a t-butyl group, an n-pentyl group, an isopentyl group, a t-pentyl group, and an n-hexyl group. Preferred examples thereof include a methyl group, an ethyl group, an n-propyl group, an isopropyl group, an n-butyl group, an isobutyl group, an s-butyl group, a t-butyl group, an n-pentyl group, an isopentyl group, a t-pentyl group, and an n-hexyl group. More preferred examples thereof include a methyl group, an ethyl group, an n-propyl group, an isopropyl group, an n-butyl group, an isobutyl group, an s-butyl group, a t-butyl group, an n-pentyl group, an isopentyl group, a t-pentyl group, and an n-hexyl group.

Specific examples of the unsubstituted aromatic hydrocarbon ring group, the unsubstituted aromatic heterocyclic group, and the unsubstituted linked aromatic group for R2 in the general formula (1) or the general formula (2) are the same as those shown above for the ring F, the ring G, and the ring J. Preferred examples thereof include benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole, and a group produced by removing one hydrogen atom from a compound formed by linking 2 to 8 these aromatic rings. More preferred examples thereof include benzene, pyridine, pyrimidine, pyrazine, quinoline, isoquinoline, quinoxaline, quinazoline, indole, benzofuran, dibenzofuran, dibenzothiophene, carbazole, and a group produced by removing one hydrogen atom from a compound formed by linking 2 to 8 these aromatic rings.

a, b, c, l, m, and n in the general formula (1) or the general formula (2) each represent the number of substitutions, a, c, and m each independently represent an integer of 0 to 4, n represents an integer of 0 to 3, and b and 1 each represent an integer of 0 to 1. Preferably, a, c, and m each independently represent an integer of 0 to 1, n represents an integer of 0 to 1, and b and I each independently represent an integer of 0 to 1.

Each pair of a pair of the ring C and the ring D, a pair of the ring E and the ring F, a pair of the ring H and the ring G, and a pair of the ring I and the ring J in the general formula (1) or the general formula (2) optionally together forms a ring via a direct bond or a linking group.

The linking group is preferably an ether group (—O—), a sulfide group (—S—), a methylene group (—C(R21)₂—), or a silyl group (—Si(R21)₂—). Here, each R21 independently represents hydrogen, an aliphatic hydrocarbon group having 1 to 8 carbon atoms, or a benzene ring, and specific examples of the aliphatic hydrocarbon group include a methyl group, an ethyl group, an n-propyl group, an isopropyl group, an n-butyl group, an isobutyl group, an s-butyl group, a t-butyl group, an n-pentyl group, an isopentyl group, a t-pentyl group, and an n-hexyl group.

Each R3 in the general formula (3) or the general formula (4) independently represents an aliphatic hydrocarbon ring group having 1 to 6 carbon atoms, a substituted or unsubstituted aromatic hydrocarbon ring group having 6 to 24 carbon atoms, or a substituted or unsubstituted aromatic heterocyclic group having 3 to 18 carbon atoms. Preferably, each R3 independently represents an aliphatic hydrocarbon group having 1 to 6 carbon atoms, a substituted or unsubstituted benzene ring group, or a substituted or unsubstituted aromatic heterocyclic group having 3 to 18 carbon atoms. More preferably, each R3 independently represents an aliphatic hydrocarbon group having 1 to 6 carbon atoms, a substituted or unsubstituted benzene ring group, or a substituted or unsubstituted aromatic heterocyclic group having 3 to 12 carbon atoms.

Specific examples of the aliphatic hydrocarbon group, the unsubstituted aromatic hydrocarbon ring group, and the unsubstituted aromatic heterocyclic group for R3 in the general formula (3) or the general formula (4) are the same as those shown for R2. Preferred examples thereof include a methyl group, an ethyl group, an n-propyl group, an isopropyl group, an n-butyl group, an isobutyl group, an s-butyl group, a t-butyl group, an n-pentyl group, an isopentyl group, a t-pentyl group, an n-hexyl group, benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, and carbazole. More preferred examples thereof include a methyl group, an ethyl group, an n-propyl group, an isopropyl group, an n-butyl group, an isobutyl group, an s-butyl group, a t-butyl group, an n-pentyl group, an isopentyl group, a t-pentyl group, an n-hexyl group, benzene, pyridine, pyrimidine, pyrazine, quinoline, isoquinoline, quinoxaline, quinazoline, indole, benzofuran, dibenzofuran, dibenzothiophene, and carbazole.

a, b, c, l, m, n, d, e, f, g, h, i, j, and k in the general formula (3) or the general formula (4) each represent the number of substitutions, g, i, and j each independently represent an integer of 0 to 5, a, c, d, e, f, h, k, and m each independently represent an integer of 0 to 4, n represents an integer of 0 to 3, and b and 1 each independently represent an integer of 0 to 1. Preferably, g, i, and j each independently represent an integer of 0 to 1, a, c, d, e, f, h, k, and m each independently represent an integer of 0 to 1, n represents an integer of 0 to 1, and b and 1 each independently represent an integer of 0 to 1.

The above emission material represented by the general formula (1) or (2) preferably has a difference between the excited singlet energy (S1) and the excited triplet energy (T1) (ΔEST), of 0.20 eV or less. In a case of small difference between S1 and T1, the reverse intersystem crossing more frequently occurs to allow efficient use of triplet excitons for emission, and thus high emission efficiency is expected to be given.

Here, the energy difference ΔEST (=S1-T1) may be determined, as described later in Examples, in such a manner that ΔEST is determined from the difference between the excited singlet energy (S1) determined by measuring an emission spectrum for a film formed to contain the emission material represented by the general formula (1) or (2) as a dopant and the excited triplet energy (T1) determined by measuring a phosphorescence spectrum for the film (that is, ΔEST for found values), or, similarly as described later in Examples, in such a manner that S1 (theo) and T1 (theo) are calculated by performing structural optimization calculation with a versatile molecular orbital method program such as Gaussian 16 at a TDA-PBE0/6-31G* level on the basis of the density functional theory (DFT), and ΔEST is determined from the difference between them (that is, ΔEST for theoretical values). Such theoretical values do not strictly match found values, but, nevertheless, are useful in relatively evaluating multiple emission materials. A preferred value of ΔEST for found values is 0.20 eV or less, and a more preferred value thereof is 0.15 eV or less. A preferred value of ΔEST for theoretical values is less than 0.55 eV, and a more preferred value thereof is less than 0.45 eV.

Specific examples of the emission materials represented by the general formula (1) or the general formula (2) are shown below, but the materials are not limited to these exemplified compounds.

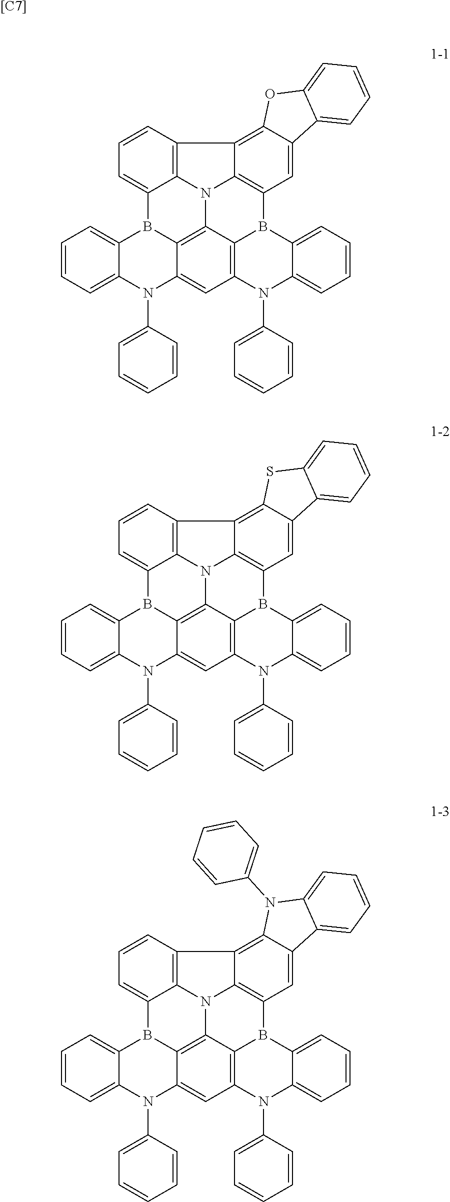

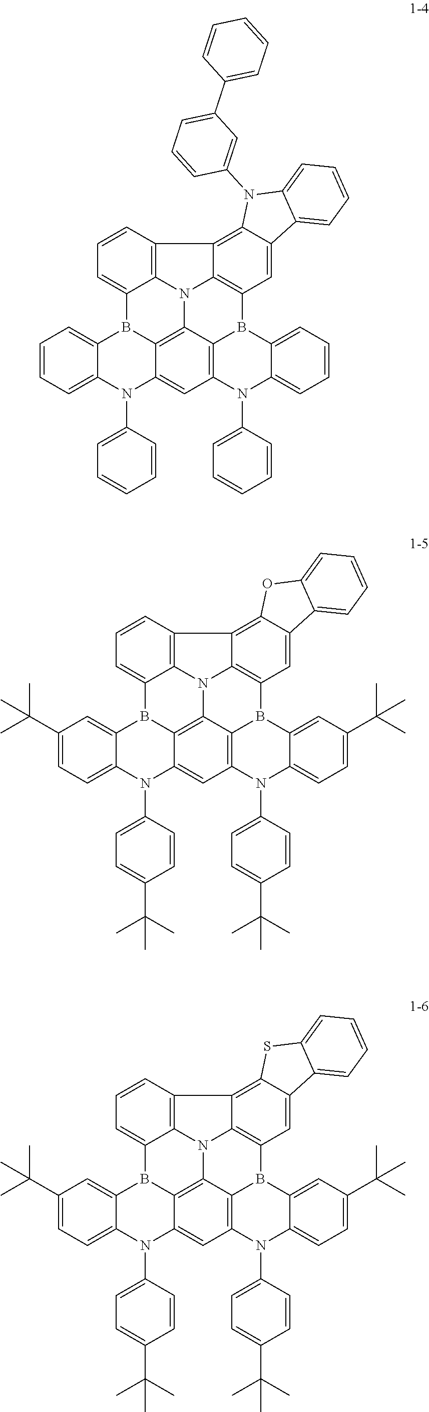

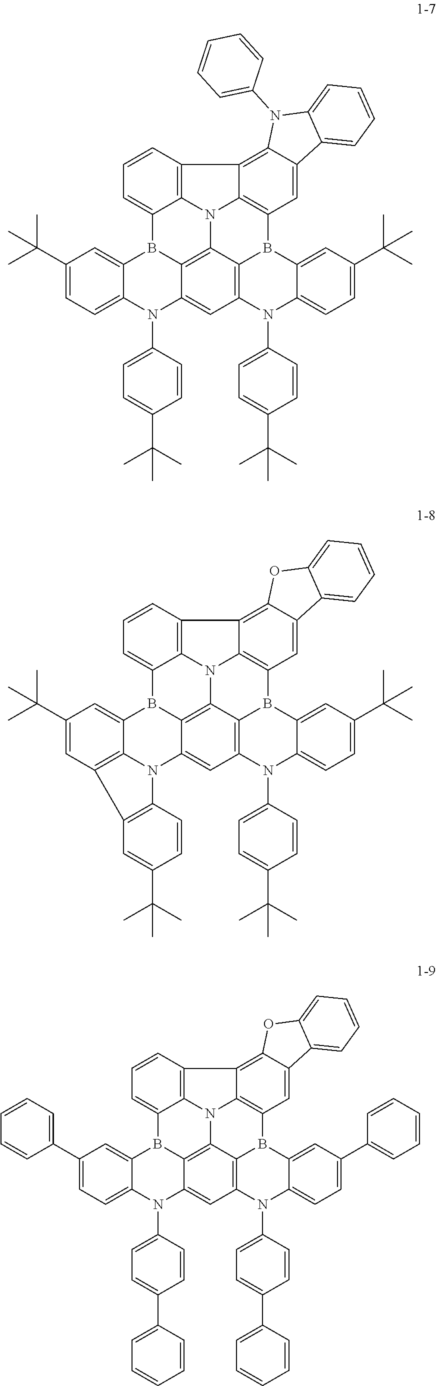

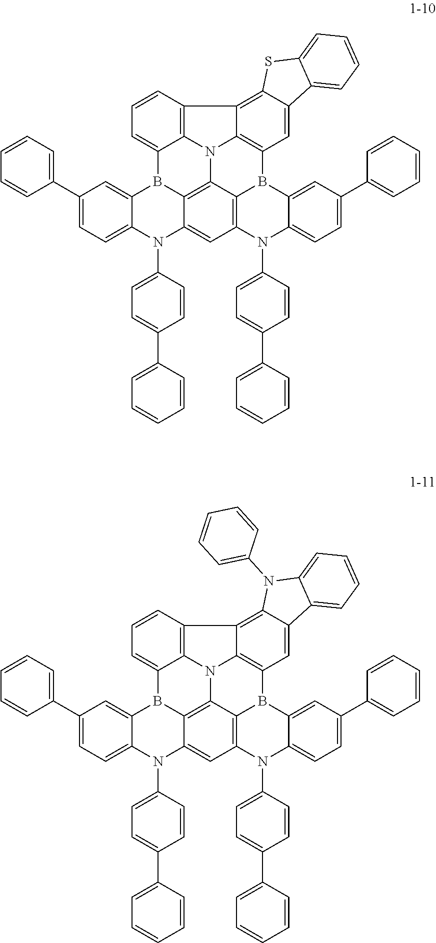

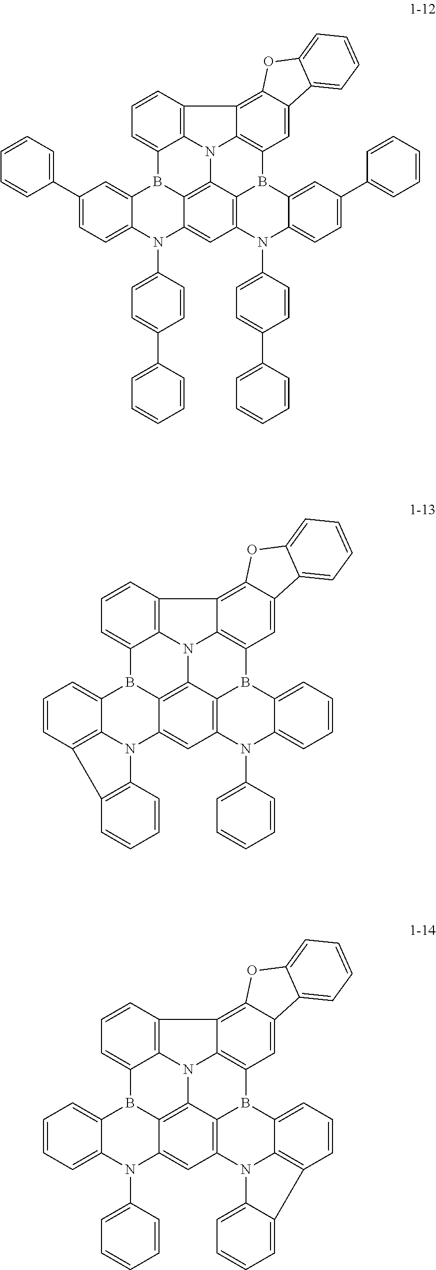

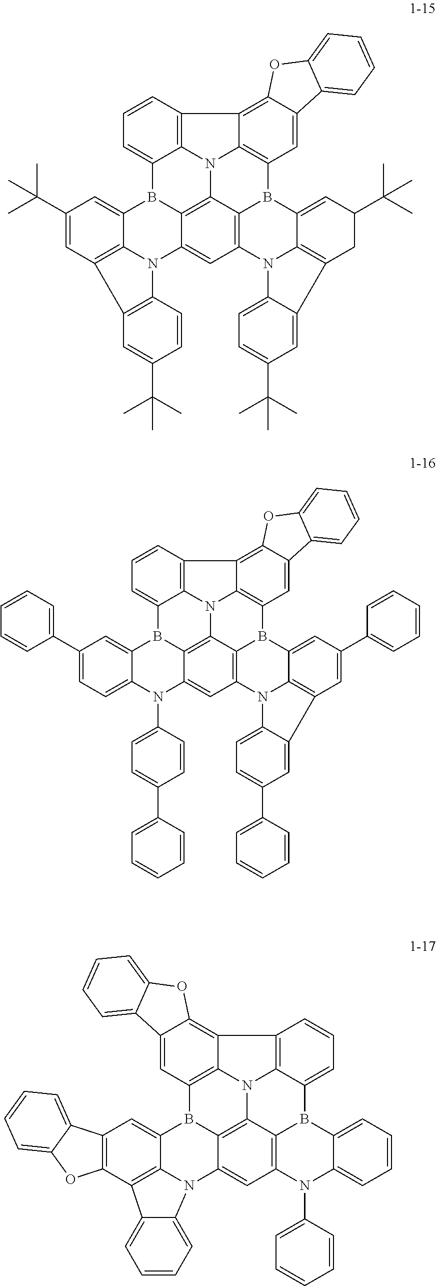

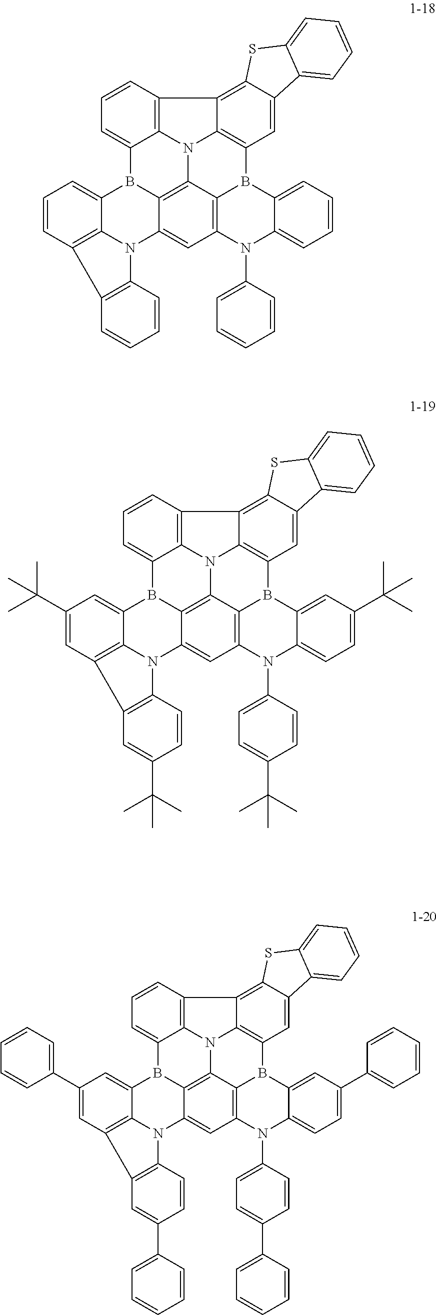

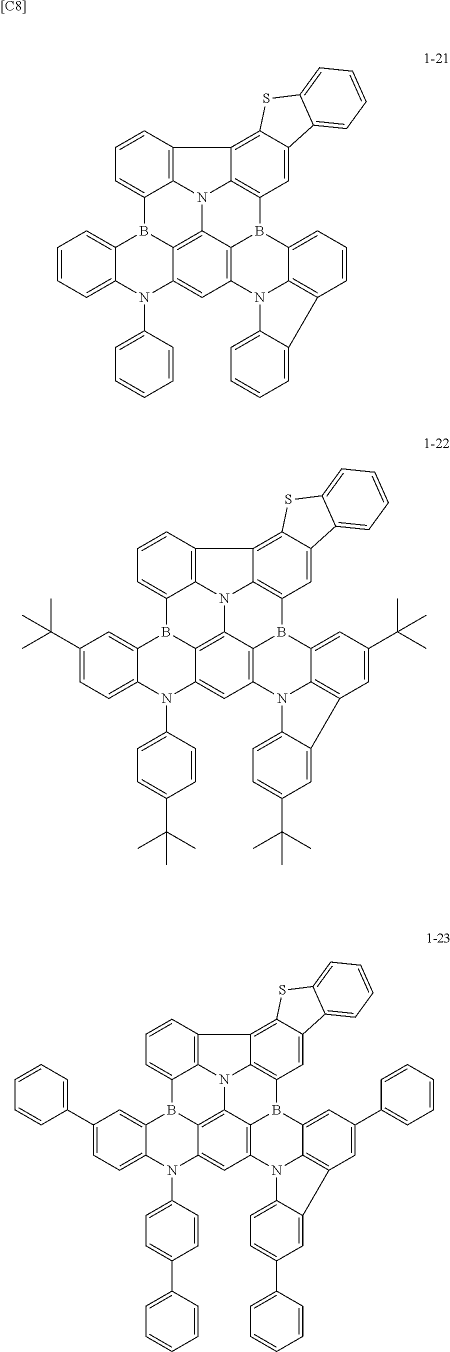

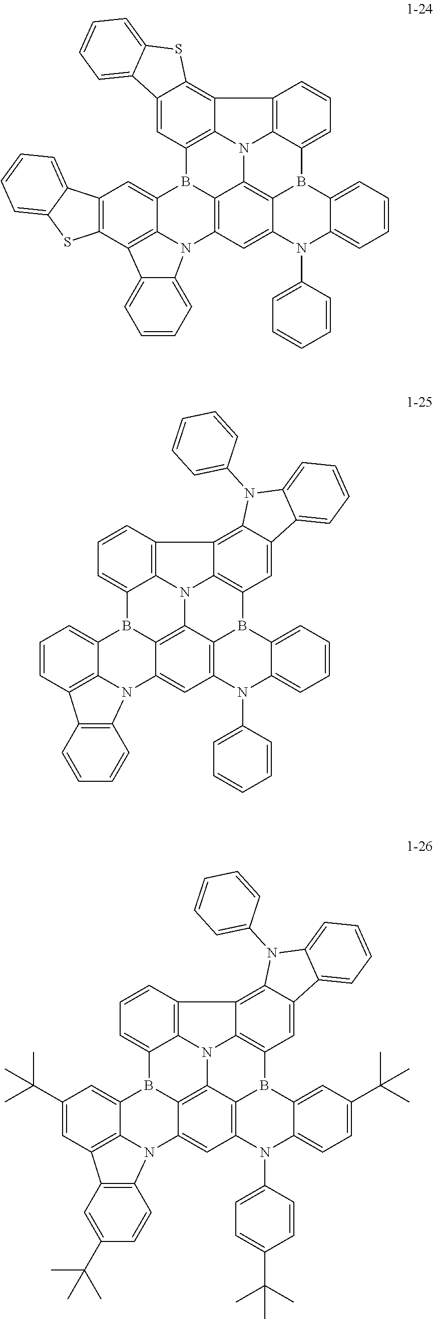

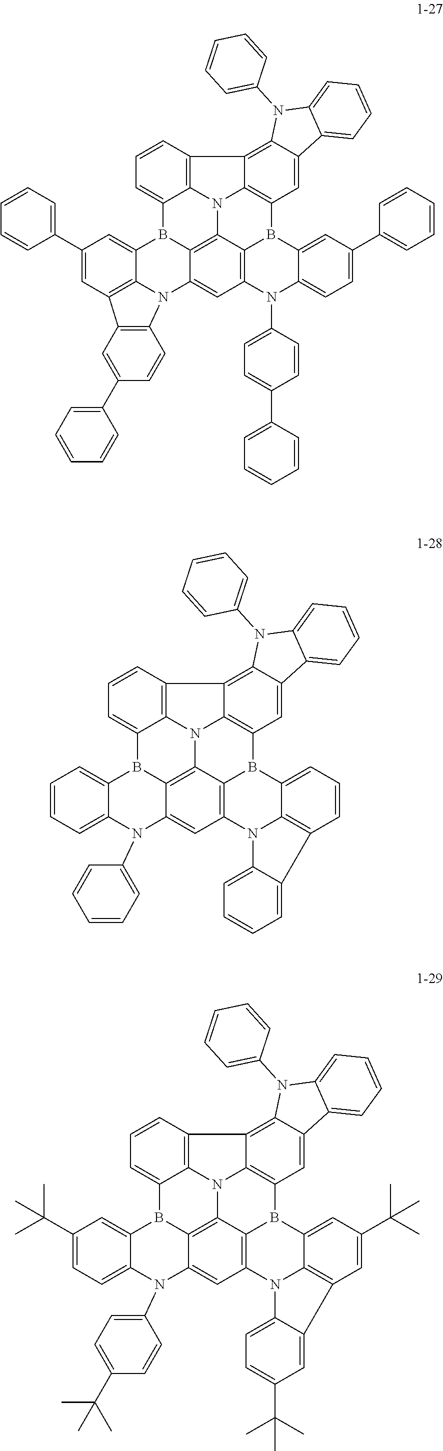

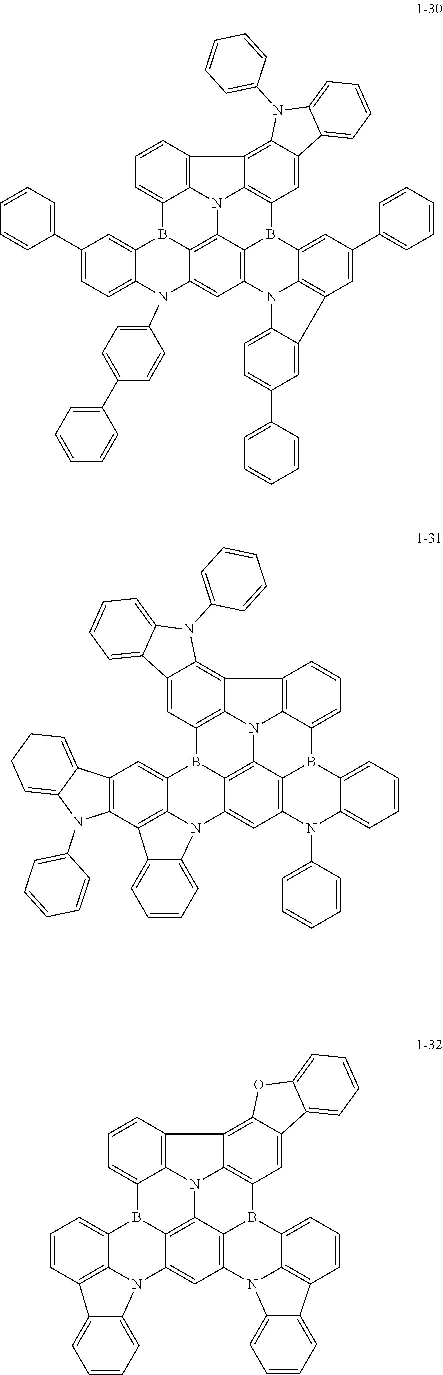

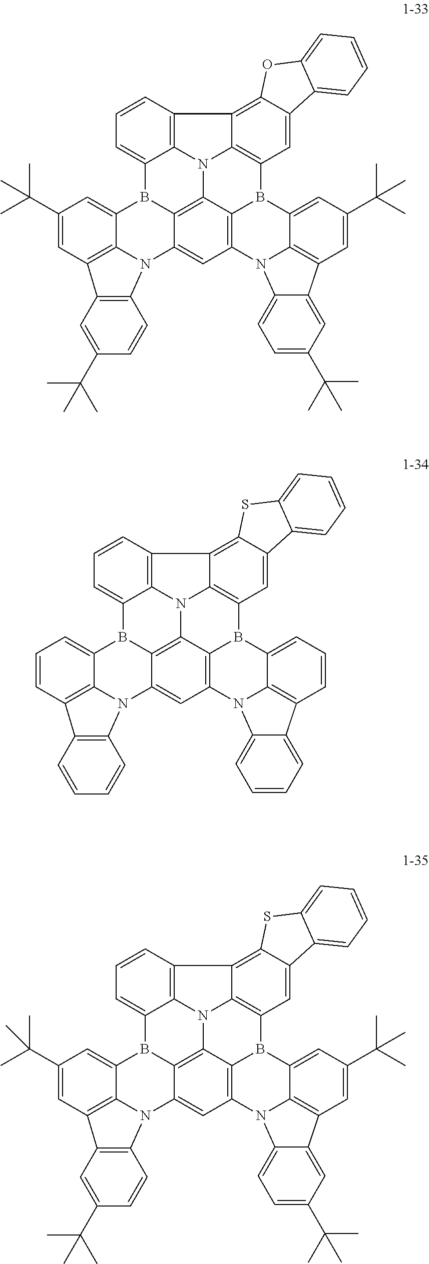

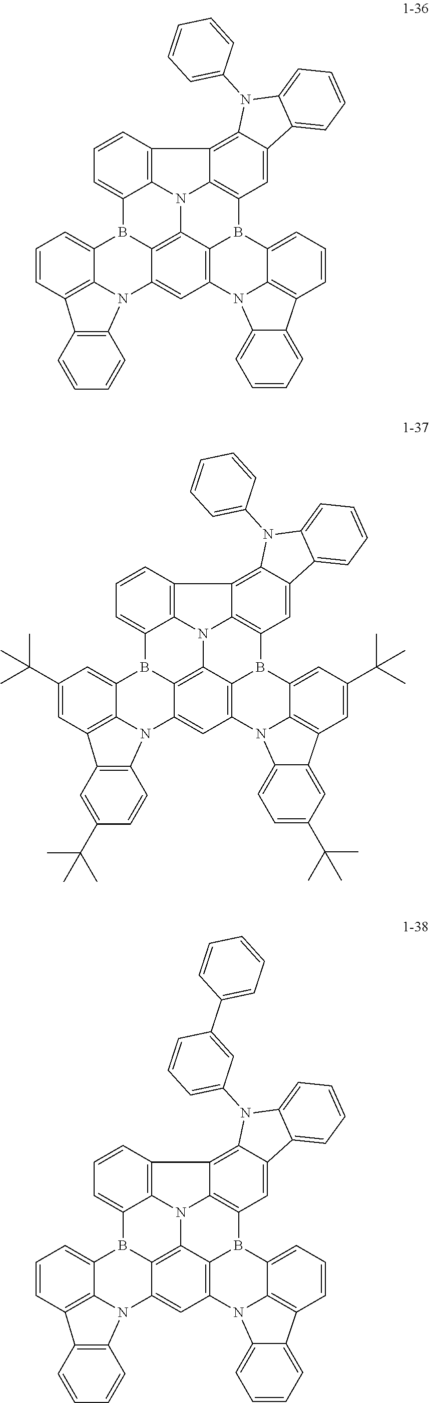

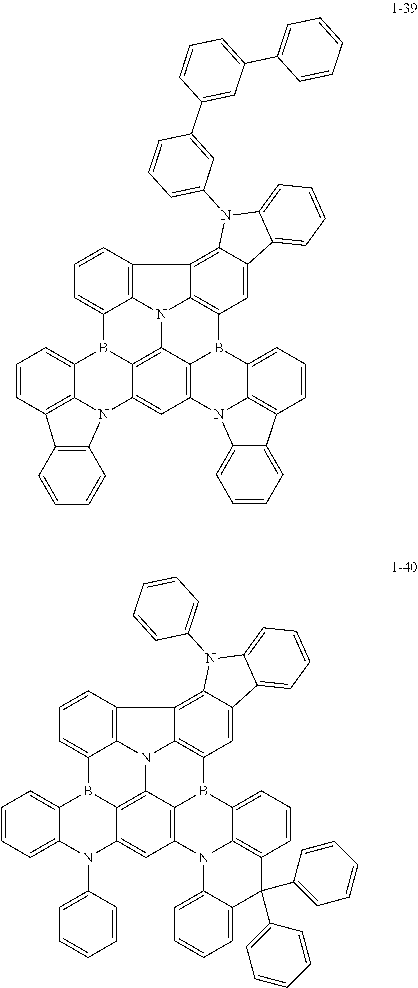

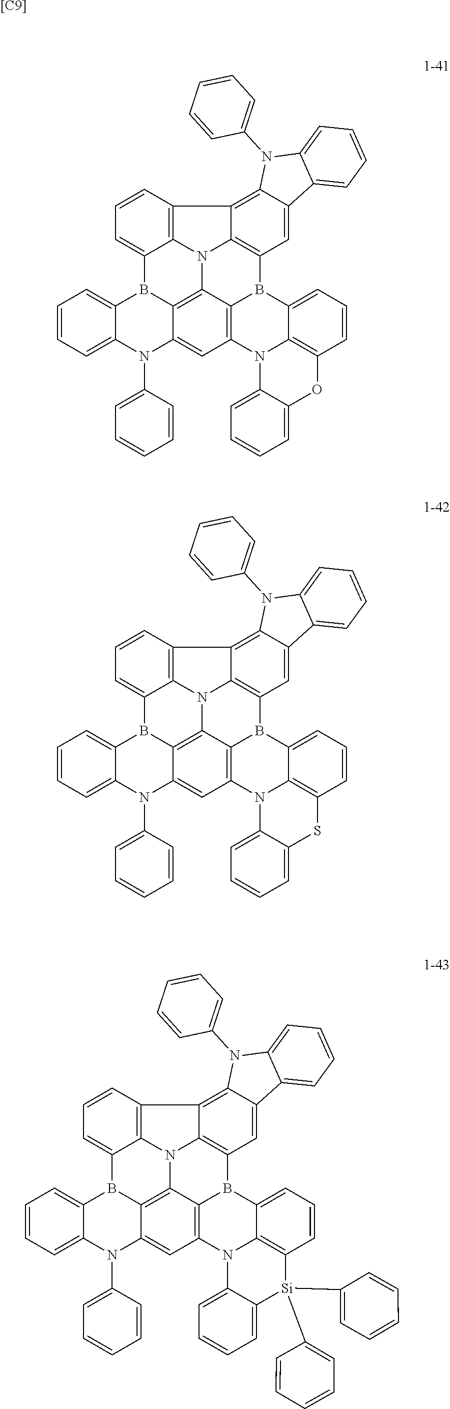

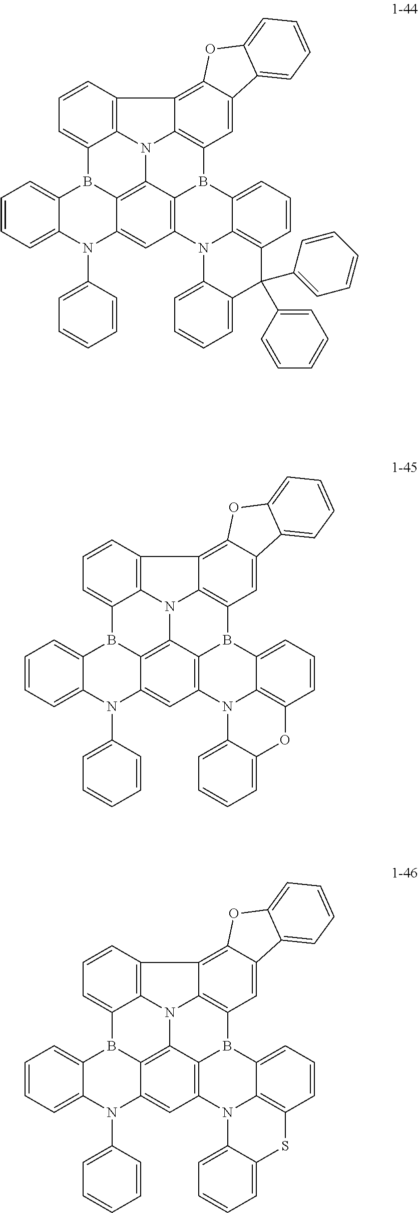

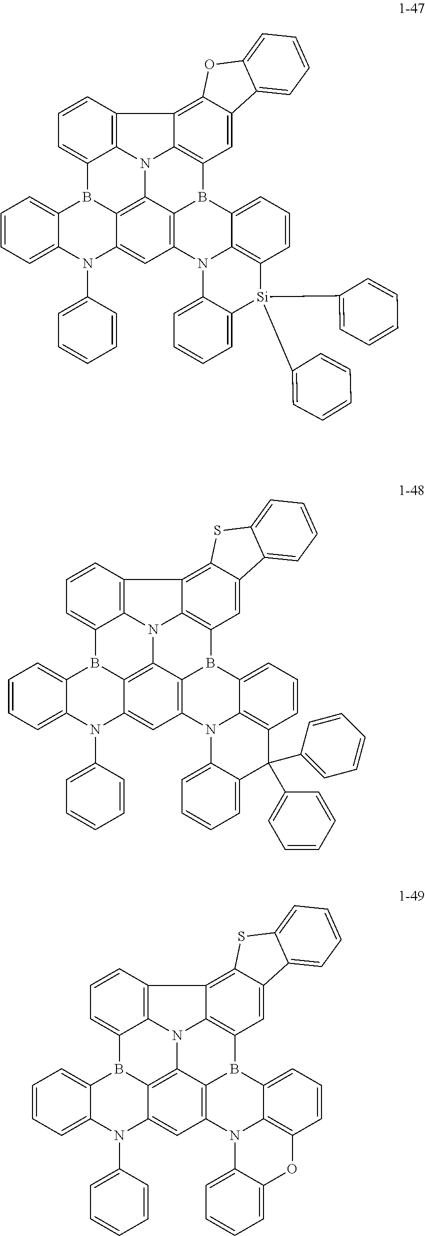

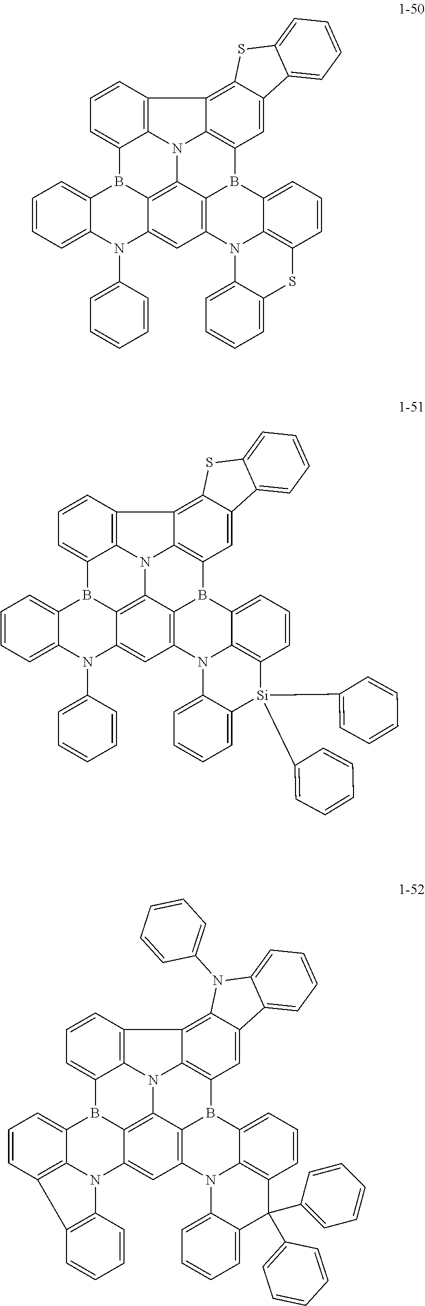

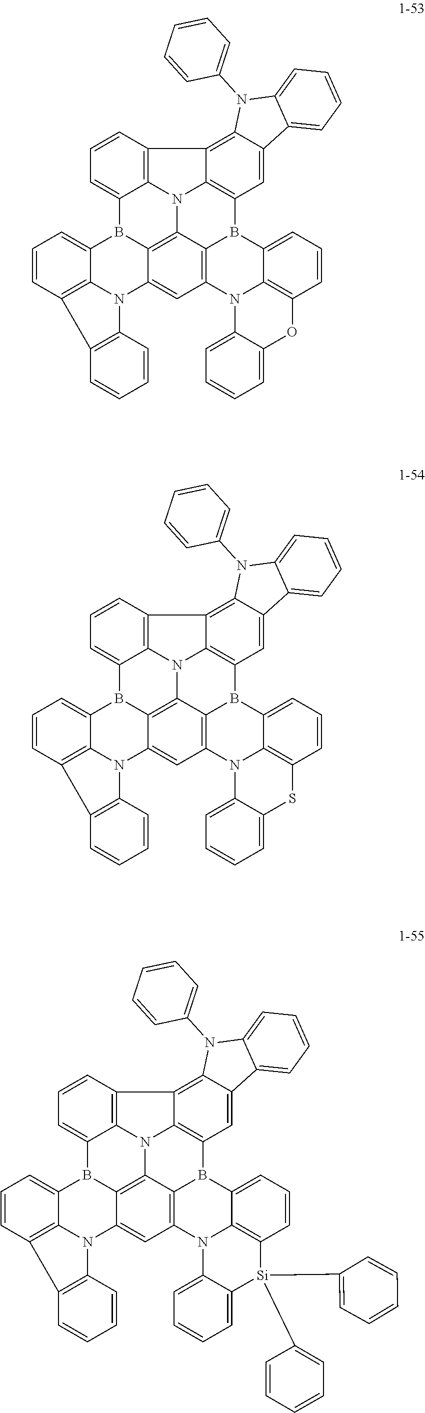

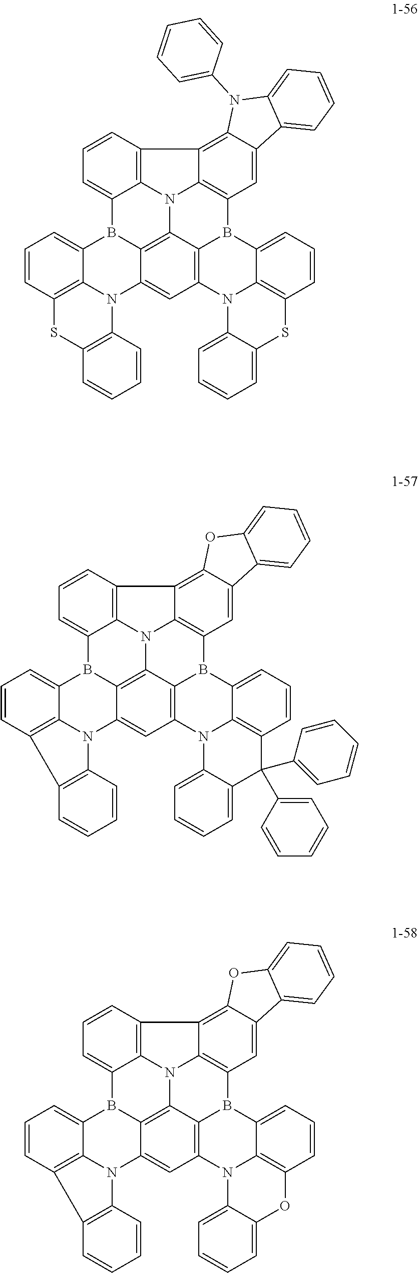

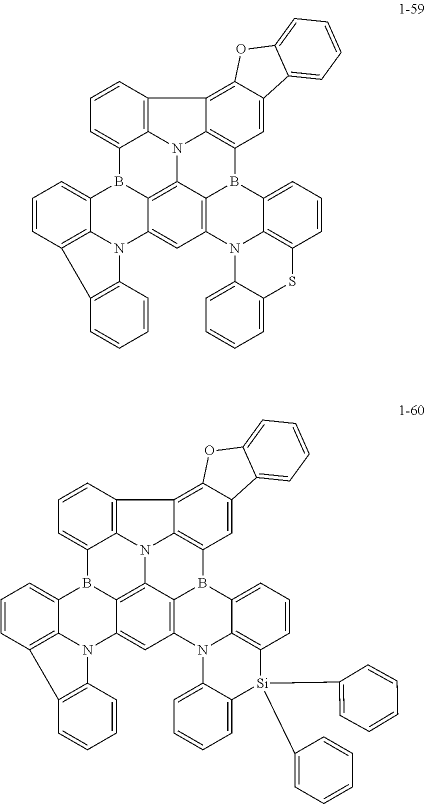

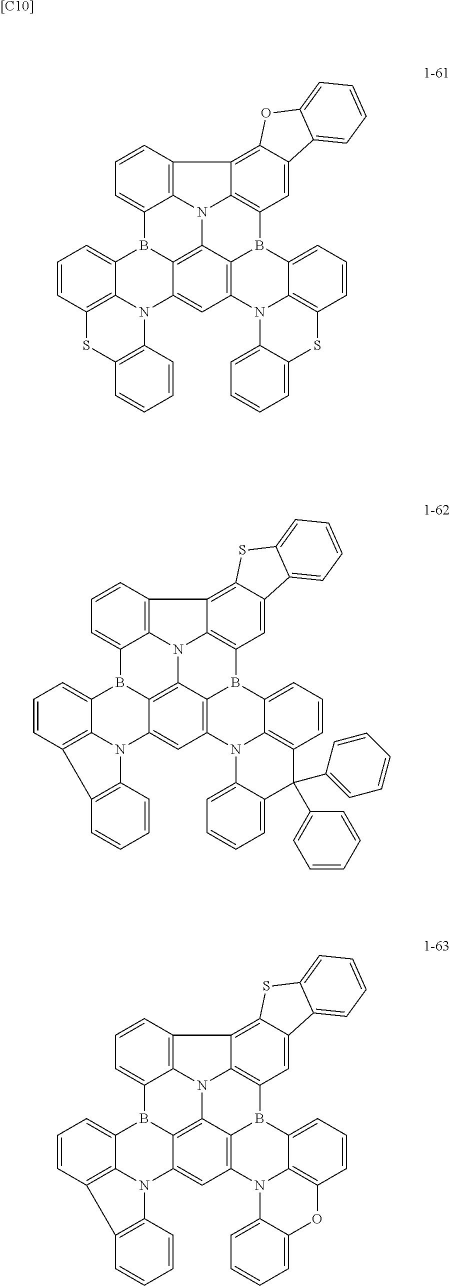

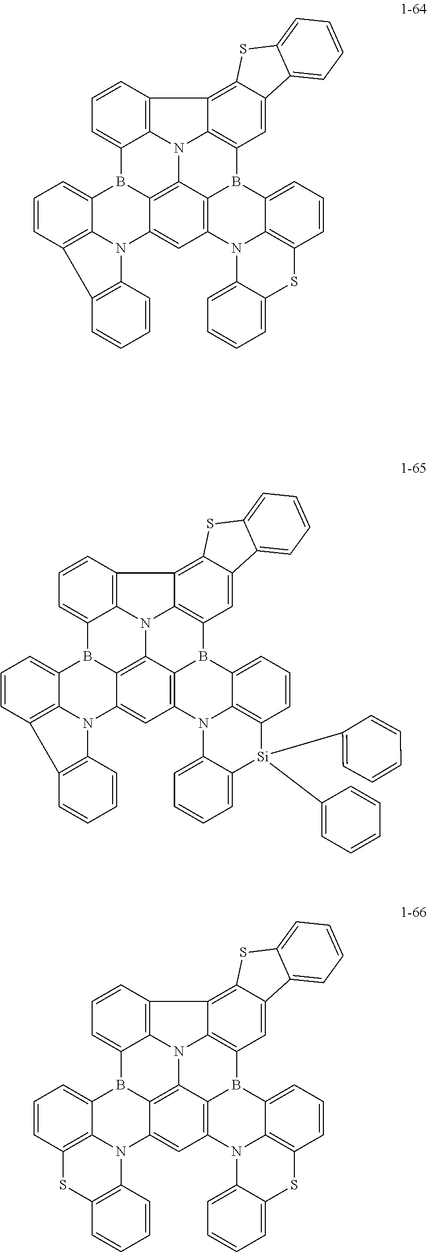

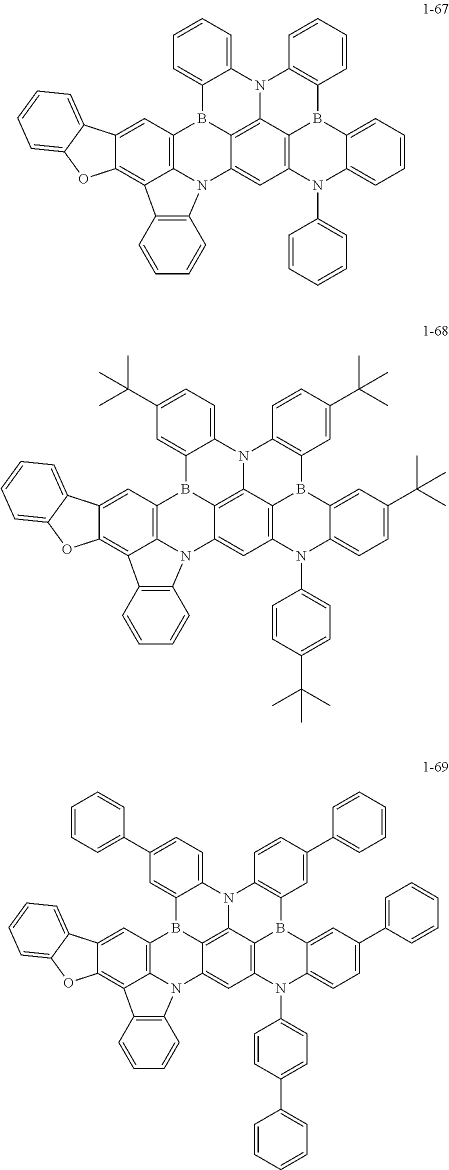

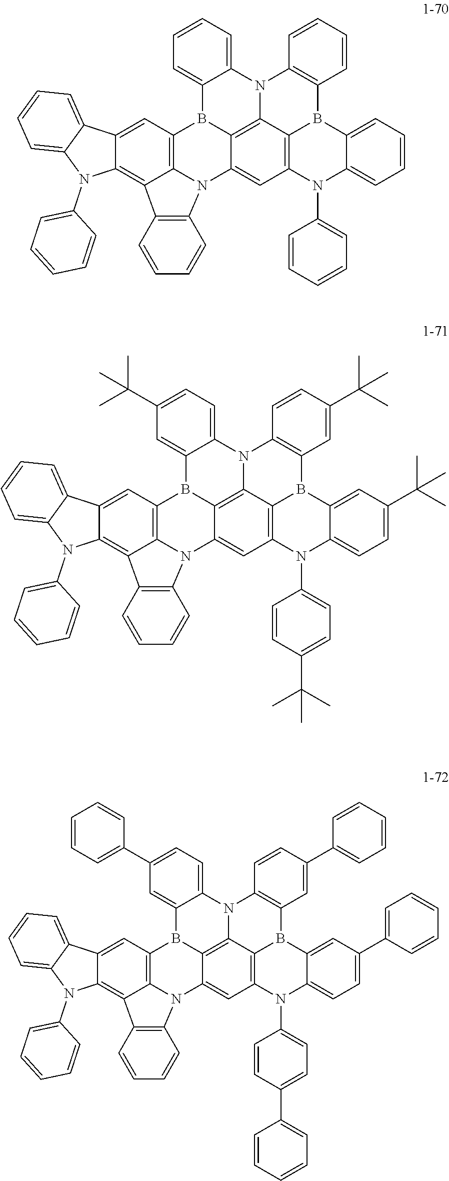

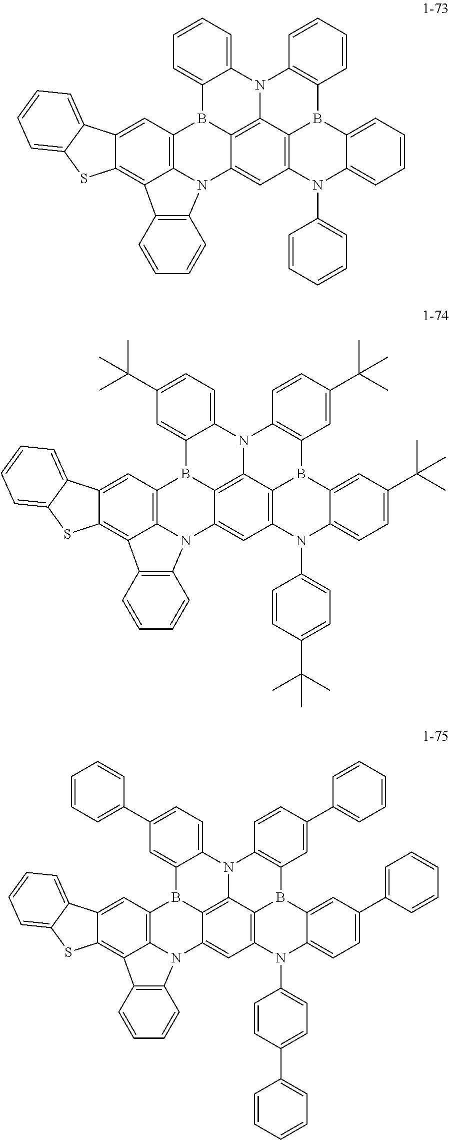

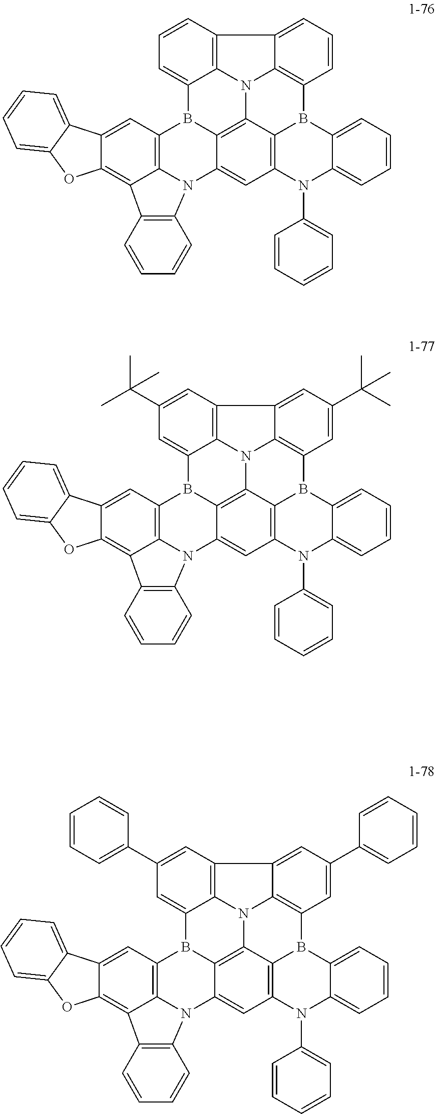

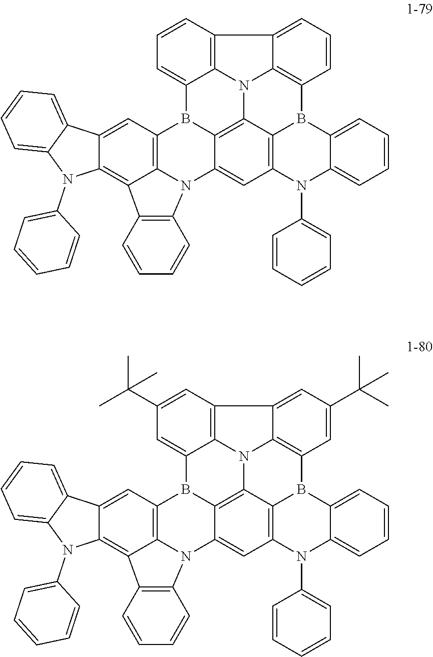

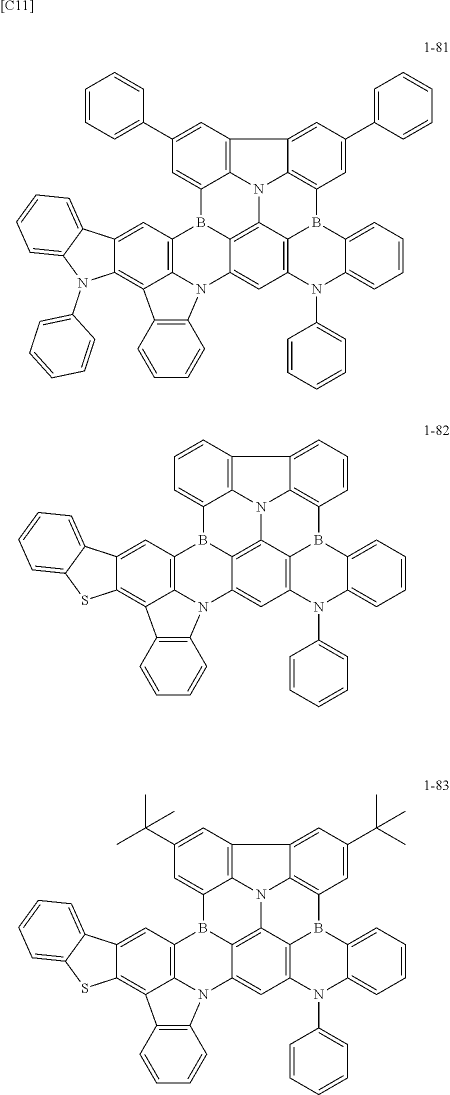

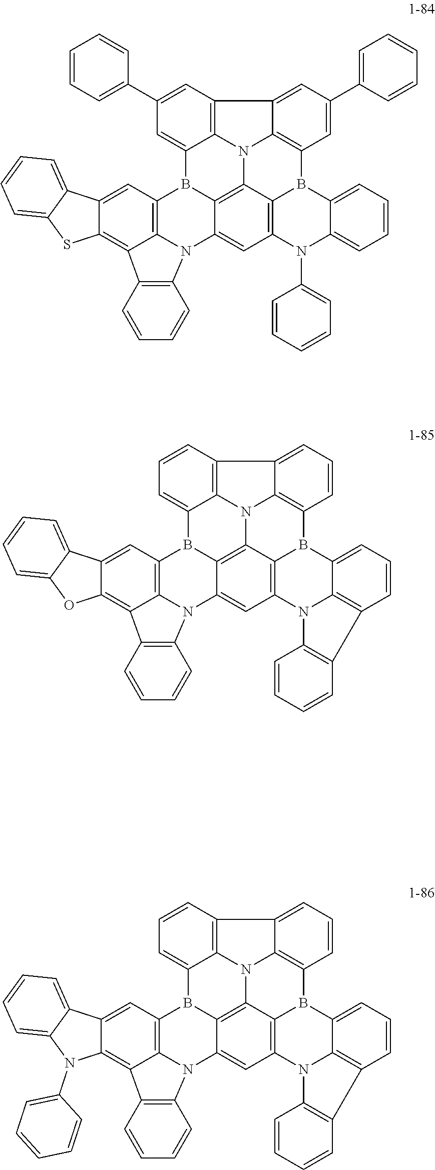

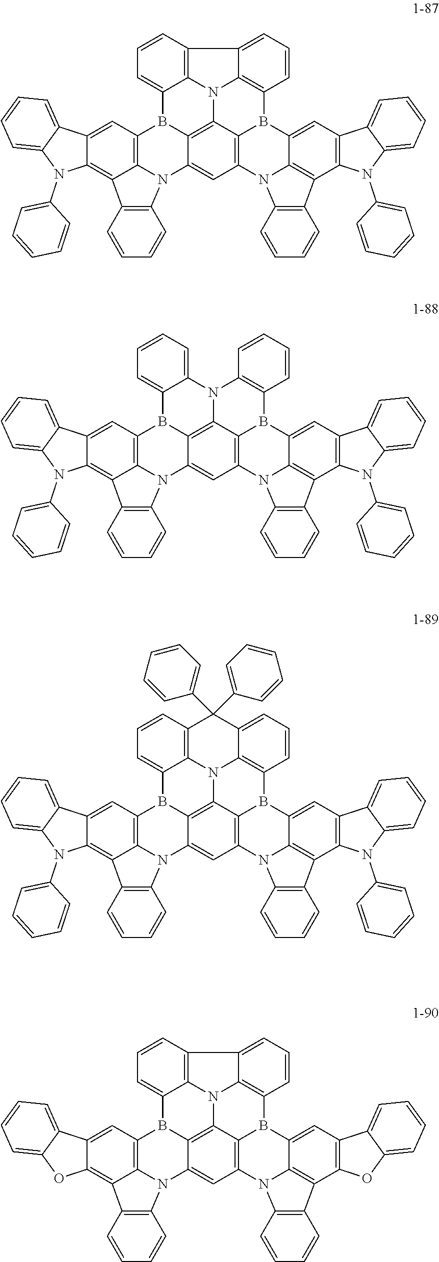

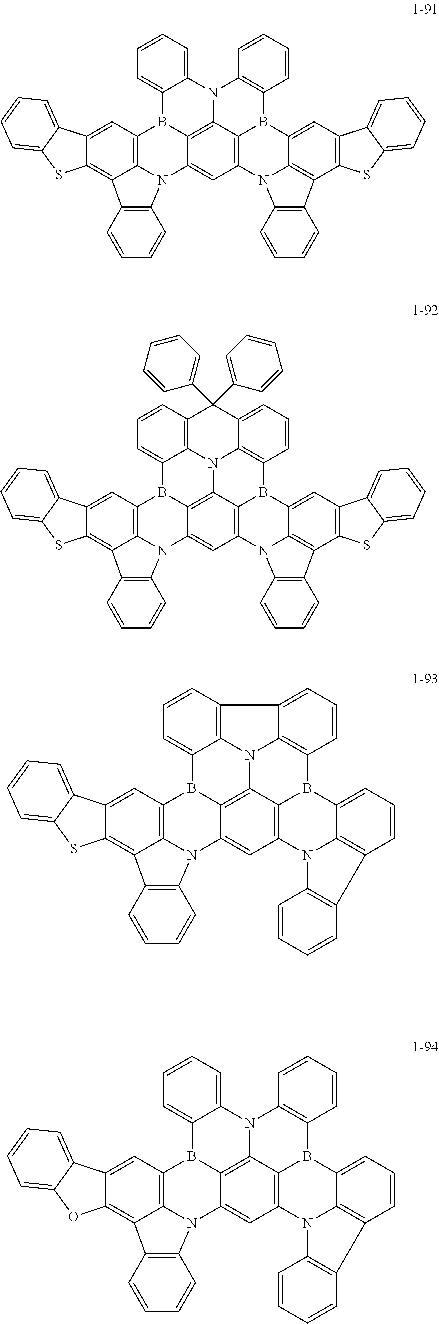

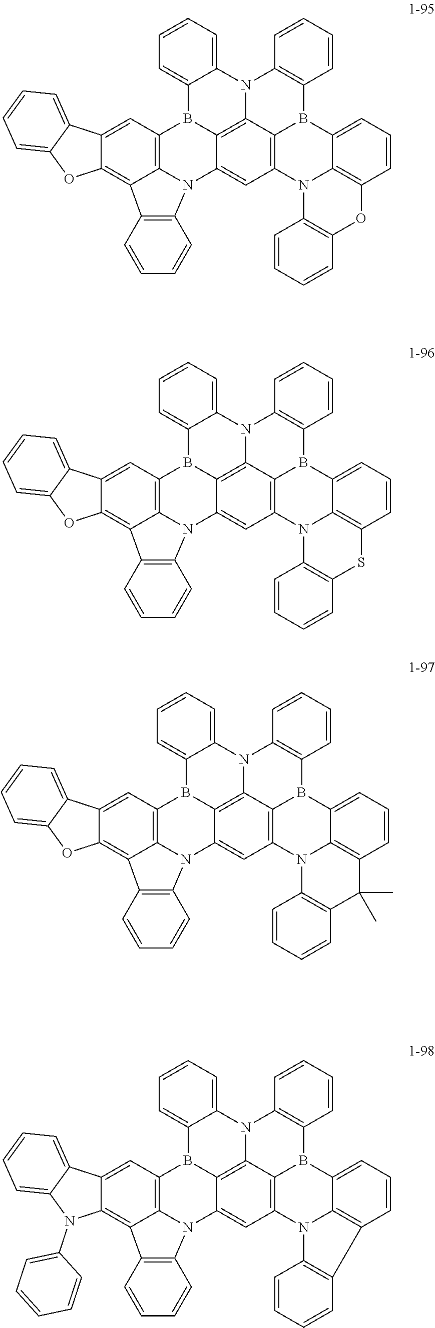

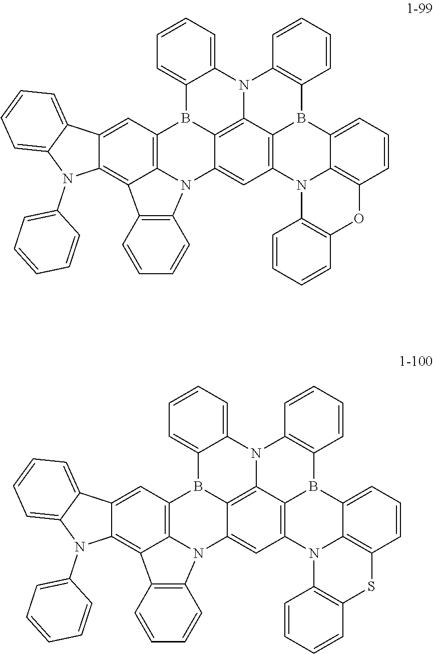

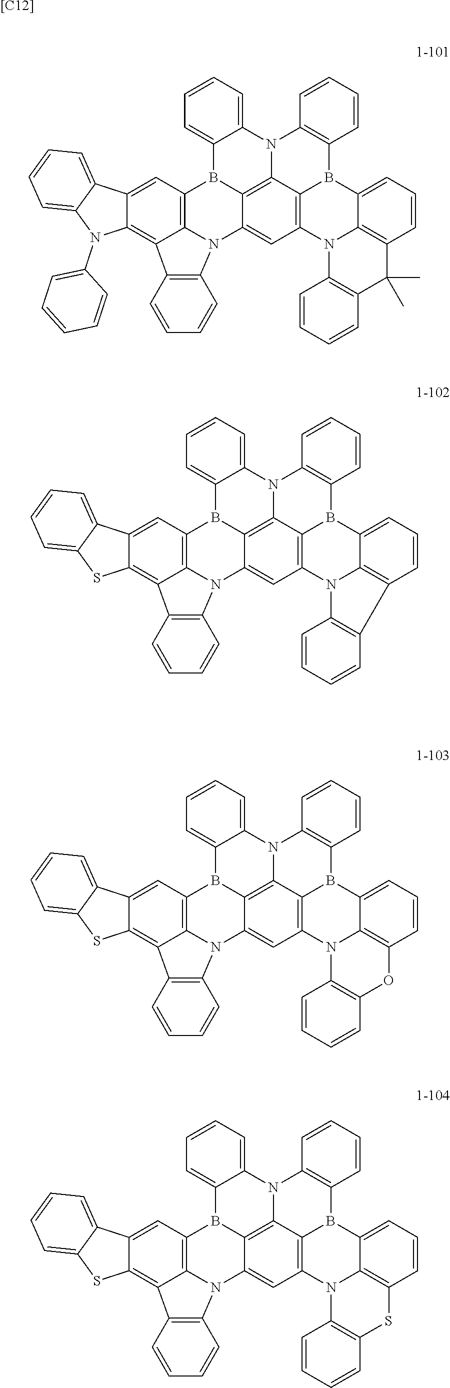

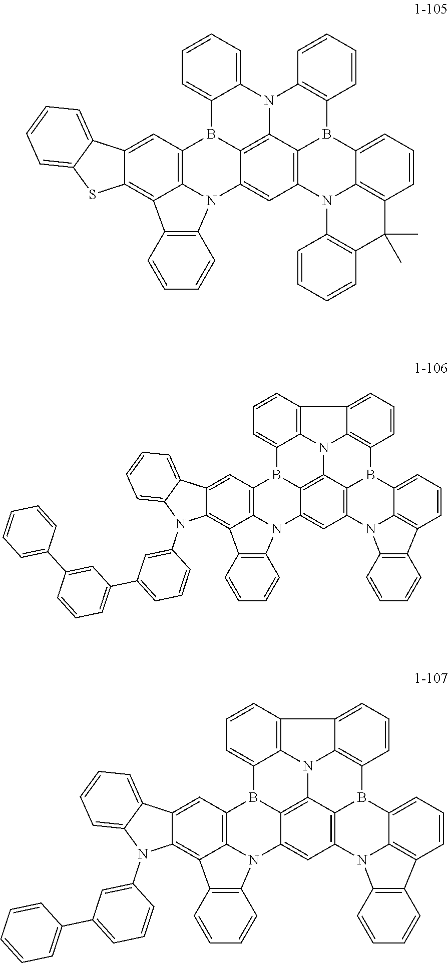

By incorporating the emission material represented by the general formula (1) or the general formula (2) into a light emitting layer, a practically excellent organic EL device having high emission efficiency and high driving stability can be provided. Preferably, by incorporating the emission material represented by the general formula (3) or the general formula (4) into a light emitting layer, a practically excellent organic EL device having high emission efficiency and high driving stability can be provided.

A more excellent organic EL device can be provided by incorporating a first host selected from compounds represented by the general formula (5) and a second host selected from compounds represented by the general formula (6) into a light emitting layer together with the emission material, as necessary.

The general formula (5) will be described.

Ar1 in the general formula (5) represents a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings. Ar1 preferably represents a substituted or unsubstituted aromatic hydrocarbon ring group having 6 to 12 carbon atoms, a substituted or unsubstituted aromatic heterocyclic group having 3 to 12 carbon atoms, or a substituted or unsubstituted linked aromatic group formed by linking 2 to 8 these aromatic rings. Ar1 more preferably represents a substituted or unsubstituted phenyl group, biphenyl group, or terphenyl group. Each of the biphenyl group and the terphenyl group may be ortho-linked, meta-linked, or para-linked, but is preferably meta-linked or para-linked.

Specific examples of the unsubstituted aromatic hydrocarbon ring group, the unsubstituted aromatic heterocyclic group, and the unsubstituted linked aromatic group for Ar1 in the general formula (5) include benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, carbazole, and a group produced by removing one hydrogen from a compound formed by linking 2 to 8 these compounds. Preferred examples thereof include benzene, naphthalene, anthracene, dibenzofuran, dibenzothiophene, carbazole, and a group produced by removing one hydrogen from a compound formed by linking 2 to 8 these compounds. More preferred examples thereof include benzene, biphenyl, and terphenyl. Each of the biphenyl group and the terphenyl group may be ortho-linked, meta-linked, or para-linked, but is preferably meta-linked or para-linked.

Each R4 in the general formula (5) independently represents an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms. Preferably, each R4 independently represents an aliphatic hydrocarbon group having 1 to 6 carbon atoms, a substituted or unsubstituted aromatic hydrocarbon ring group having 6 to 12 carbon atoms, or a substituted or unsubstituted aromatic heterocyclic group having 3 to 12 carbon atoms.

Specific examples of the aliphatic hydrocarbon group, the unsubstituted aromatic hydrocarbon ring group, and the unsubstituted aromatic heterocyclic group for R4 in the general formula (5) include a methyl group, an ethyl group, an n-propyl group, an isopropyl group, an n-butyl group, an isobutyl group, an s-butyl group, a t-butyl group, an n-pentyl group, an isopentyl group, a t-pentyl group, an n-hexyl group, benzene, naphthalene, acenaphthene, acenaphthylene, azulene, anthracene, chrysene, pyrene, phenanthrene, triphenylene, fluorene, benzo[a]anthracene, pyridine, pyrimidine, triazine, thiophene, isothiazole, thiazole, pyridazine, pyrrole, pyrazole, imidazole, triazole, thiadiazole, pyrazine, furan, isoxazole, quinoline, isoquinoline, quinoxaline, quinazoline, thiadiazole, phthalazine, tetrazole, indole, benzofuran, benzothiophene, benzoxazole, benzothiazole, indazole, benzimidazole, benzotriazole, benzisothiazole, benzothiadiazole, purine, pyranone, coumarin, isocoumarin, chromone, dibenzofuran, dibenzothiophene, dibenzoselenophene, and carbazole. Preferred examples thereof include a methyl group, a t-butyl group, benzene, naphthalene, dibenzofuran, dibenzothiophene, dibenzoselenophene, and carbazole.

In the general formula (5), q and r each independently represent an integer of 0 to 4, o and p each represent an integer of 0 to 3, s represents an integer of 1 to 4, and t represents 1 or 2. Preferably, q and r each independently represent an integer of 0 to 1, p represents an integer of 0 to 1, s represents an integer of 1 to 3, and t represents 1.

The general formula (5) contains at least two or more carbazoles, and in this case preferably contains a carbazole linked at 3,9-position or 4,9-position.

A hydrogen atom in the general formula (5) is optionally replaced with a deuterium atom.

Specific examples of the emission materials represented by the general formula (5) are shown below, but the materials are not limited to these exemplified compounds.

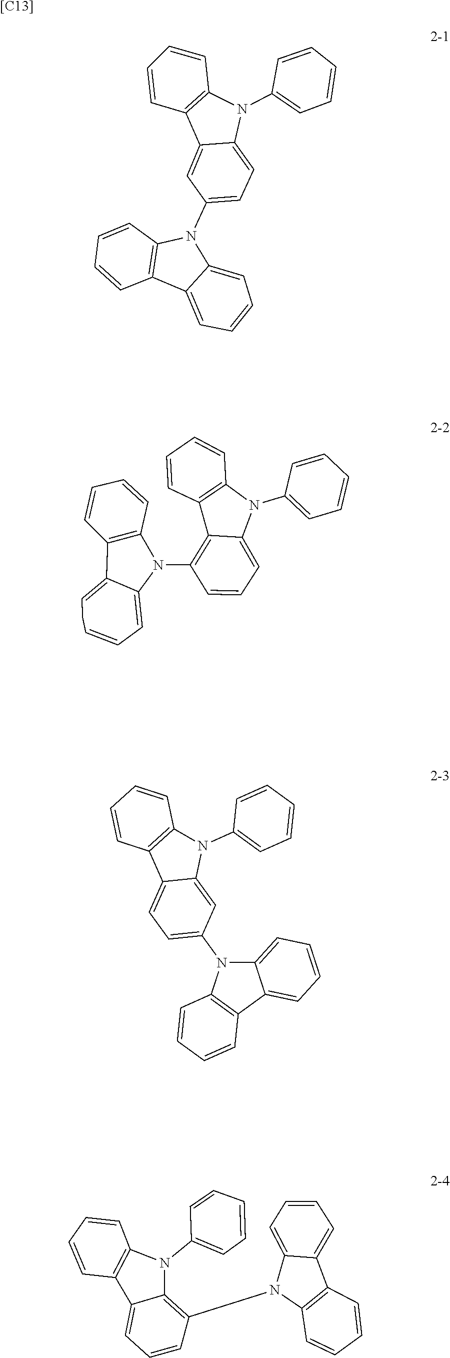

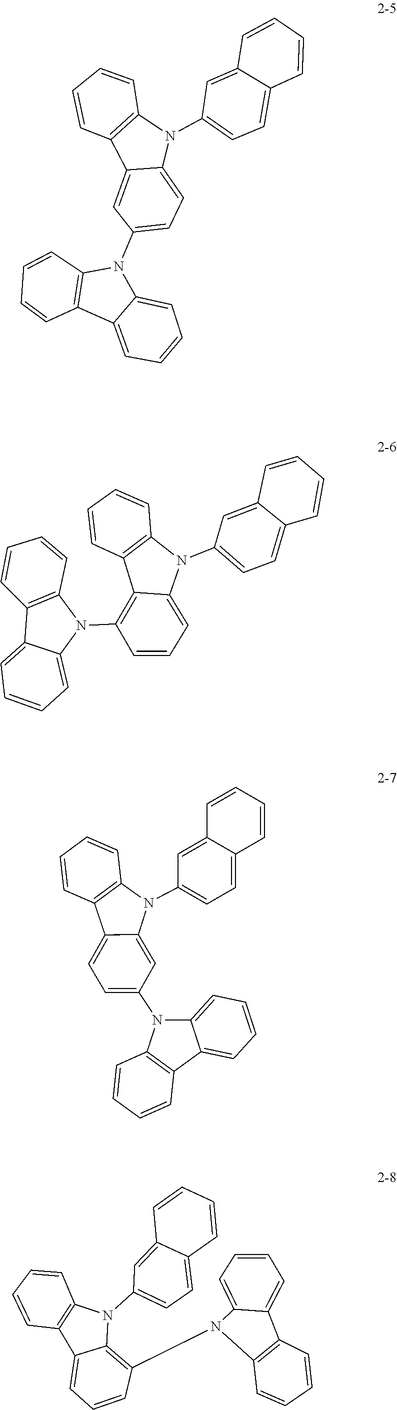

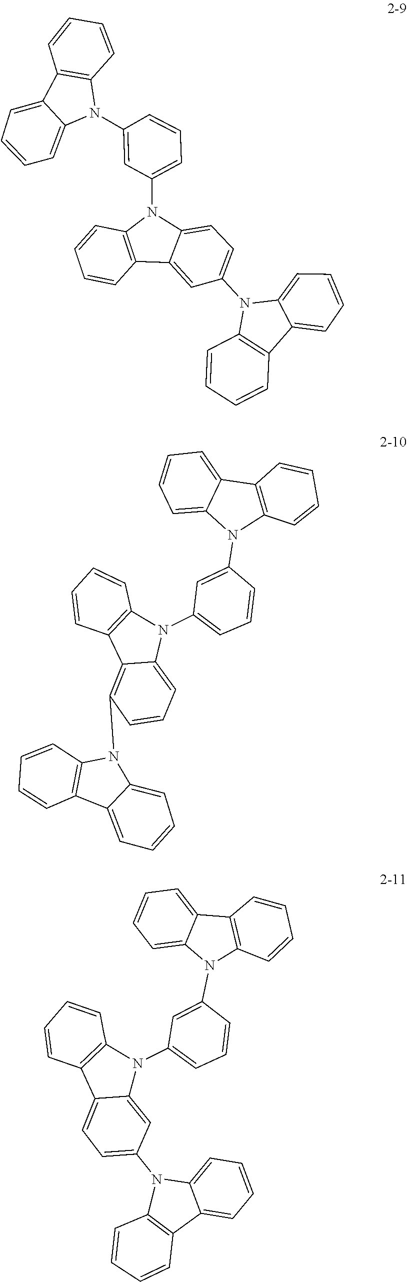

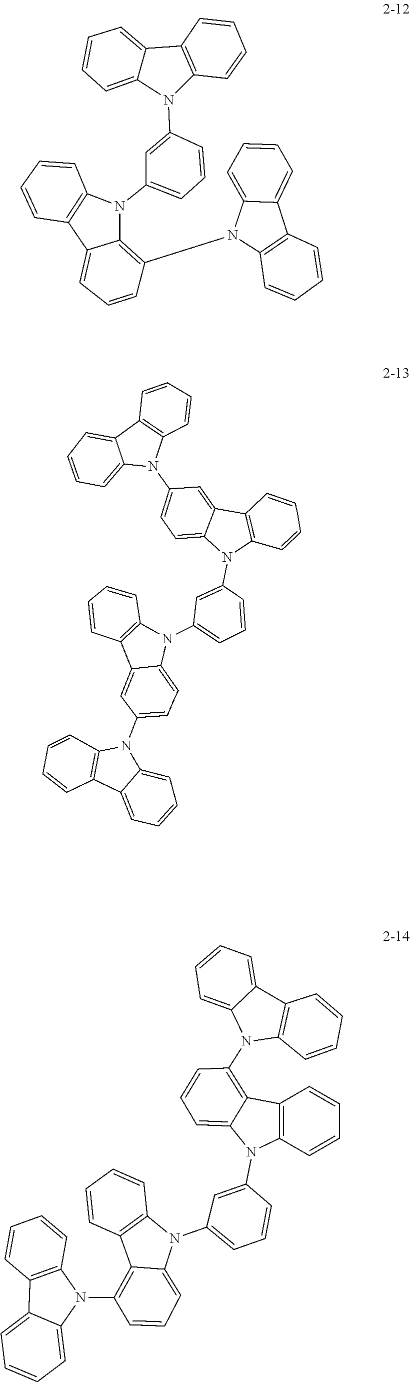

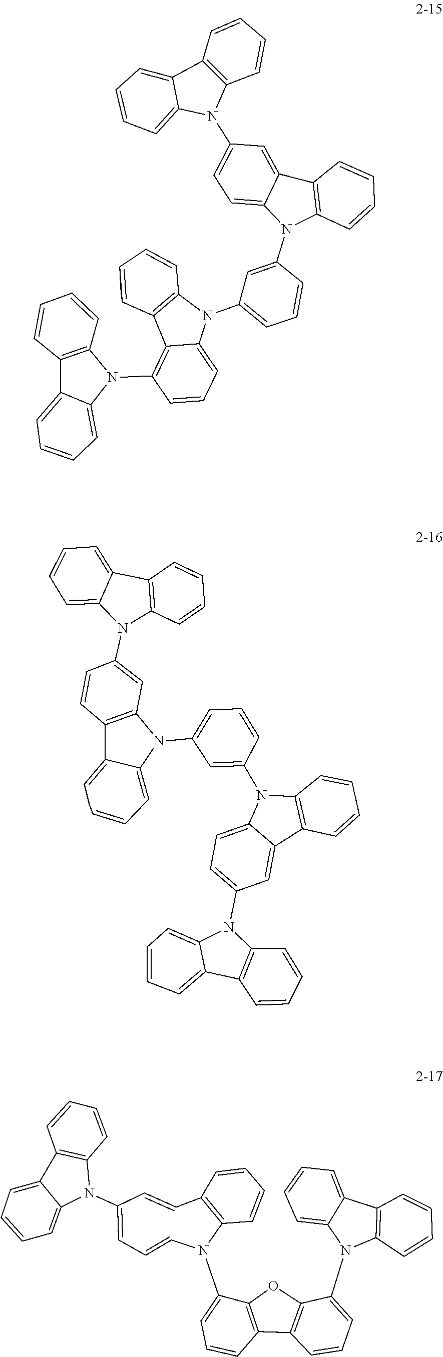

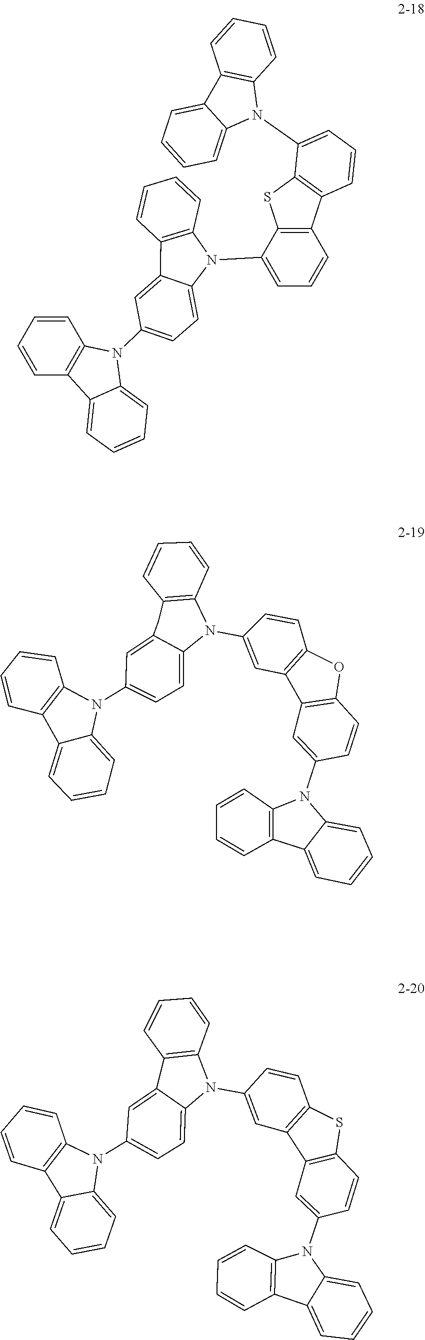

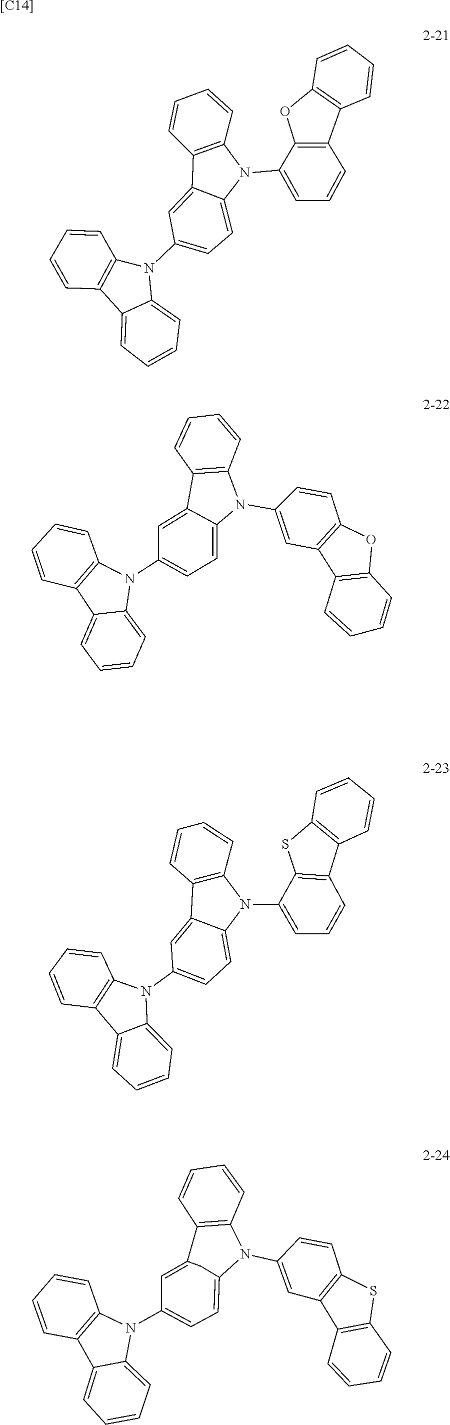

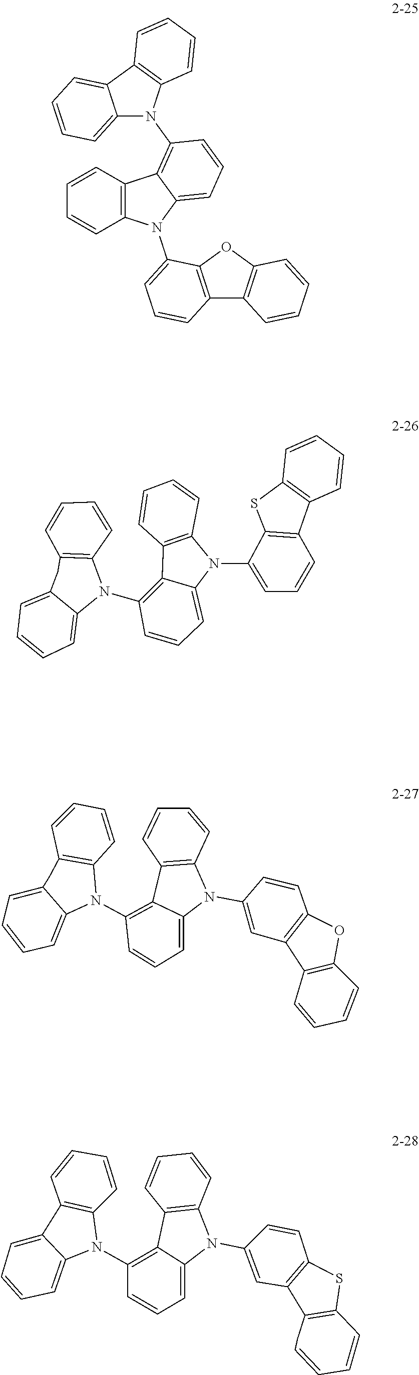

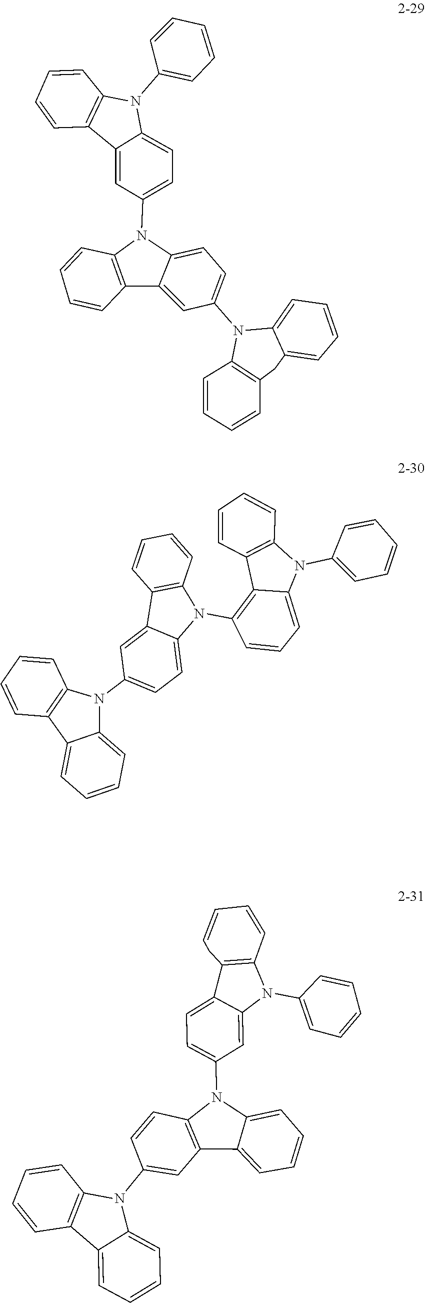

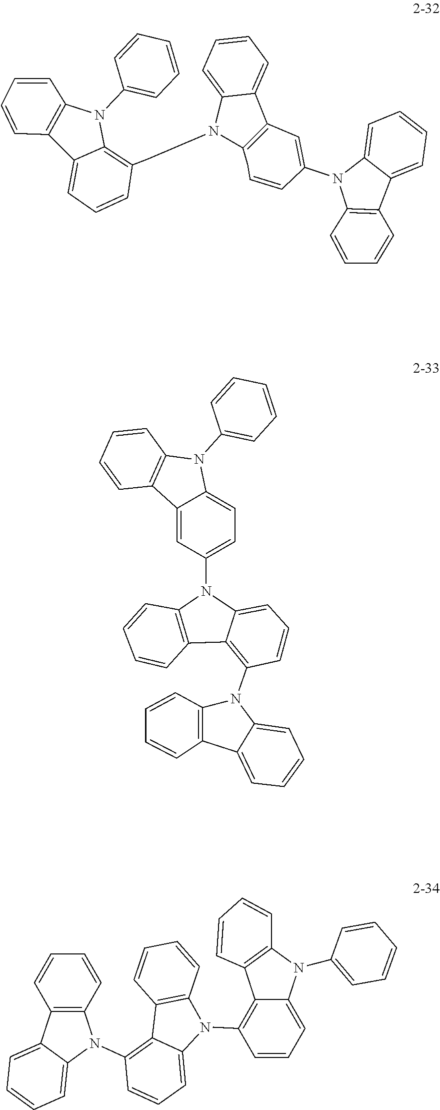

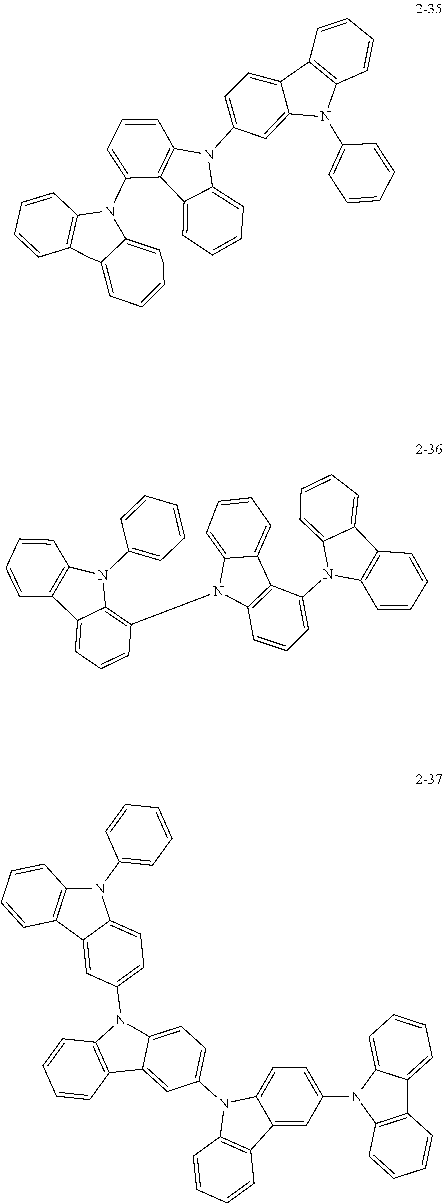

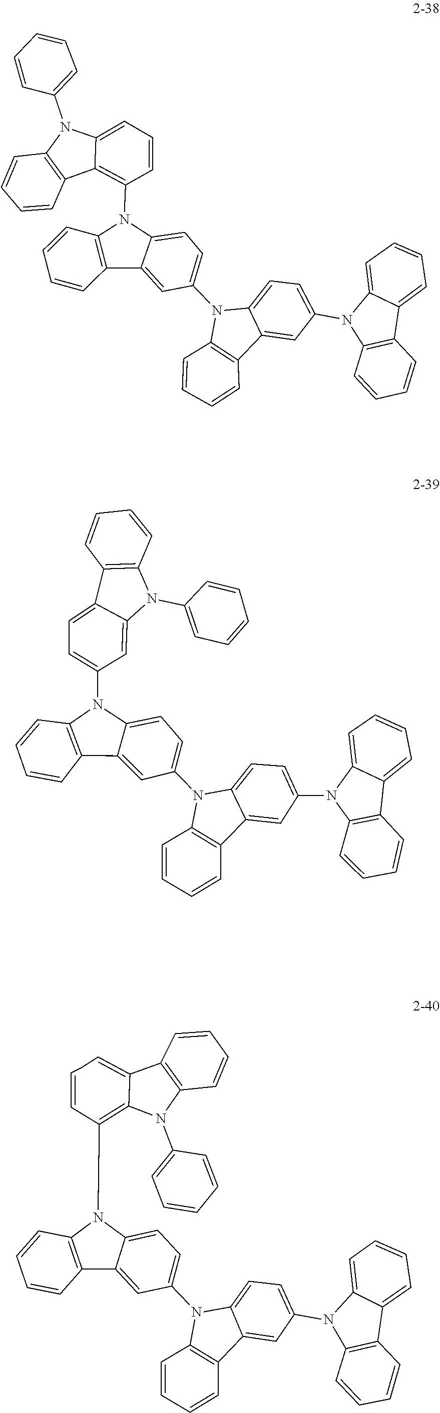

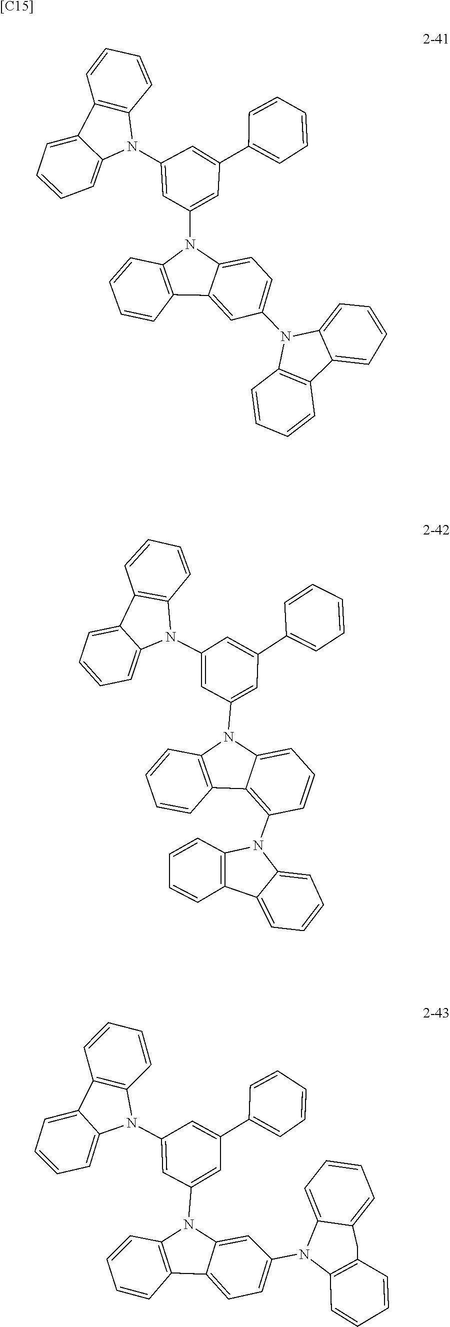

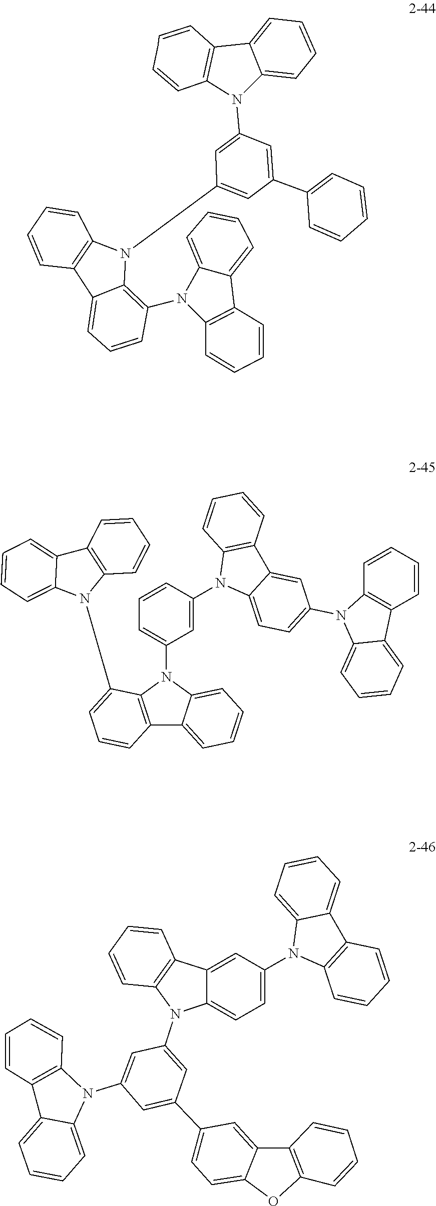

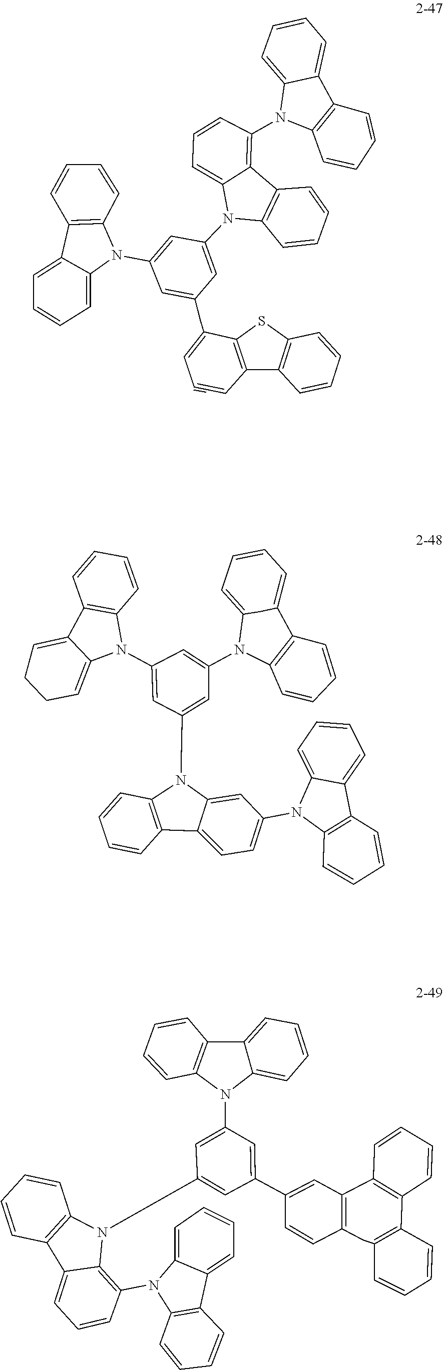

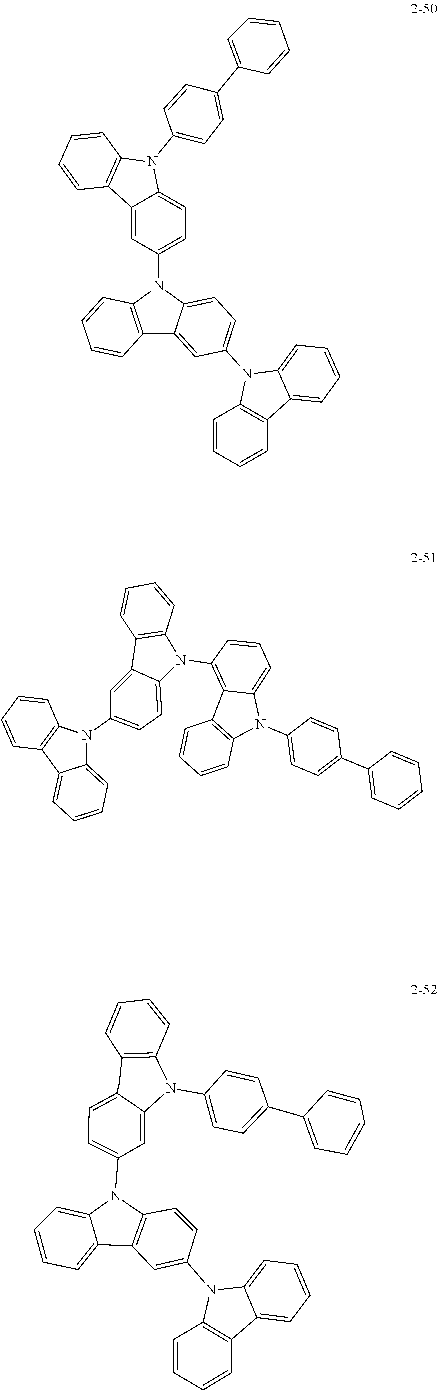

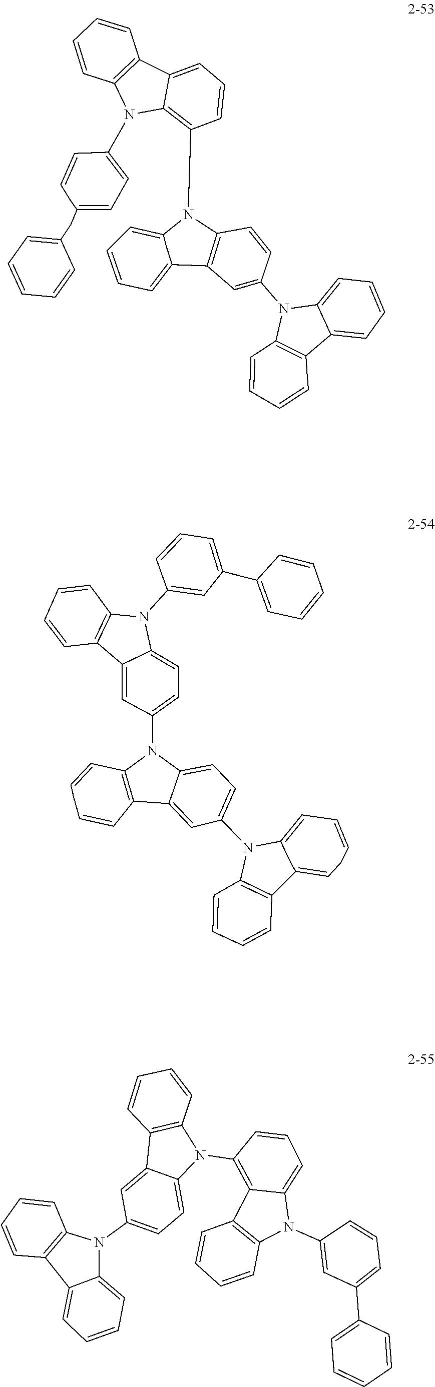

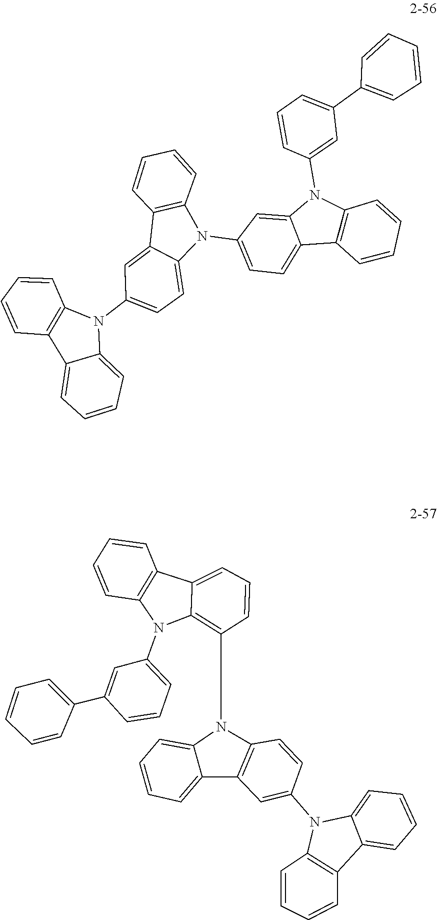

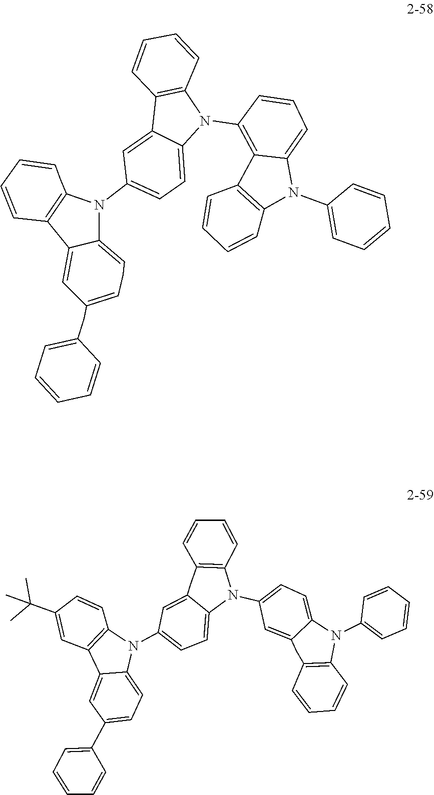

Next, the general formula (6) will be described.

Each X2 in the general formula (6) represents N or C—R5, provided that at least one X2 represents N. Preferably, three X2 each represent N.

Each R5 in the general formula (6) independently represents hydrogen, deuterium, an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms. Preferably, each R5 independently represents hydrogen, deuterium, an aliphatic hydrocarbon group having 1 to 6 carbon atoms, a substituted or unsubstituted aromatic hydrocarbon ring group having 6 to 12 carbon atoms, or a substituted or unsubstituted aromatic heterocyclic group having 3 to 12 carbon atoms. Specific examples thereof are the same as those described for R4, except that hydrogen and deuterium are included. Preferred examples thereof include hydrogen, deuterium, a methyl group, a t-butyl group, benzene, naphthalene, dibenzofuran, dibenzothiophene, dibenzoselenophene, and carbazole.

Ar2, Ar3, and Ar4 in the general formula (6) each have the same meaning as Ar1 in the general formula (5). Specifically, Ar2, Ar3, and Ar4 each independently represent a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings. Preferably, Ar2, Ar3, and Ar4 each independently represent an aromatic hydrocarbon ring group having 6 to 12 carbon atoms, a substituted or unsubstituted aromatic heterocyclic group having 3 to 12 carbon atoms, or a substituted or unsubstituted linked aromatic group formed by linking 2 to 8 these aromatic rings. More preferably, Ar2, Ar3, and Ar4 each independently represent a substituted or unsubstituted benzene ring group, a substituted or unsubstituted aromatic heterocyclic group having 3 to 12 carbon atoms, or a substituted or unsubstituted linked aromatic group formed by linking 2 to 8 these aromatic rings. Specific examples thereof are as shown for Ar1. Preferred examples thereof include benzene, naphthalene, dibenzofuran, dibenzothiophene, dibenzoselenophene, carbazole, and a substituted or unsubstituted linked aromatic group formed by linking 2 to 8 these aromatic rings. More preferred examples thereof include benzene, biphenyl, terphenyl, dibenzofuran, and carbazole. Each of the biphenyl group and the terphenyl group may be ortho-linked, meta-linked, or para-linked, but is preferably meta-linked or para-linked.

At least one of Ar2, Ar3, and Ar4 is preferably a substituted or unsubstituted aromatic hydrocarbon ring group having 6 to 18 carbon atoms, or a substituted or unsubstituted linked aromatic group formed by linking 2 to 3 these aromatic rings.

A hydrogen atom in the general formula (6) is optionally replaced with a hydrogen atom.

Specific examples of the emission materials represented by the general formula (6) shown below, but the materials are not limited to these exemplified compounds.

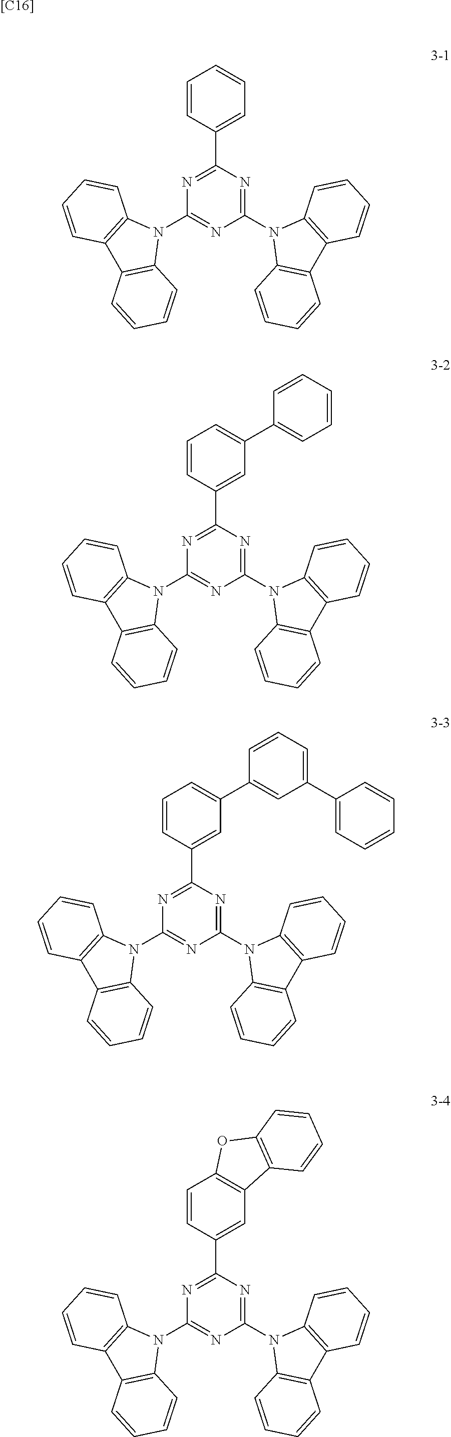

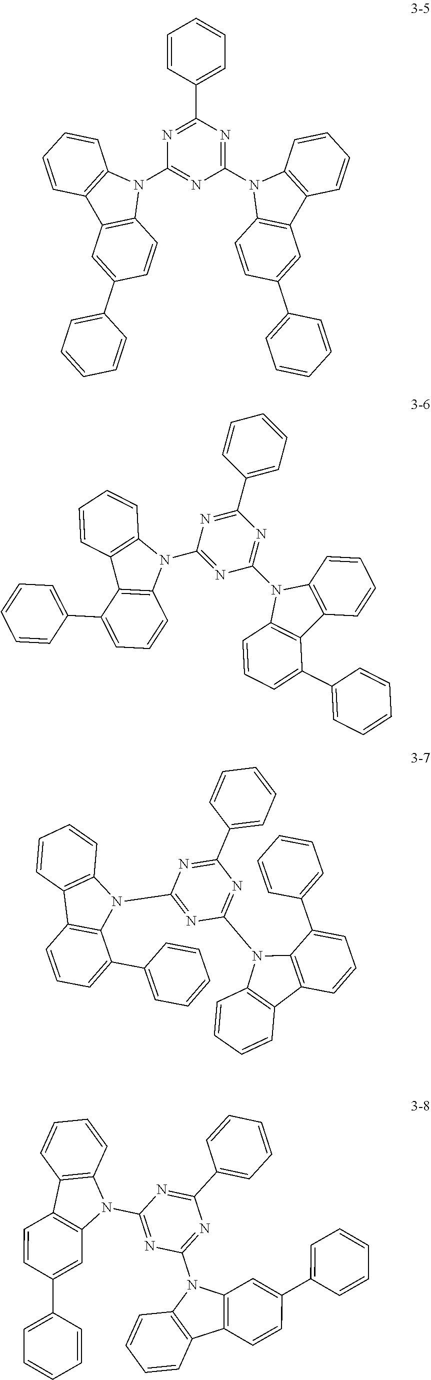

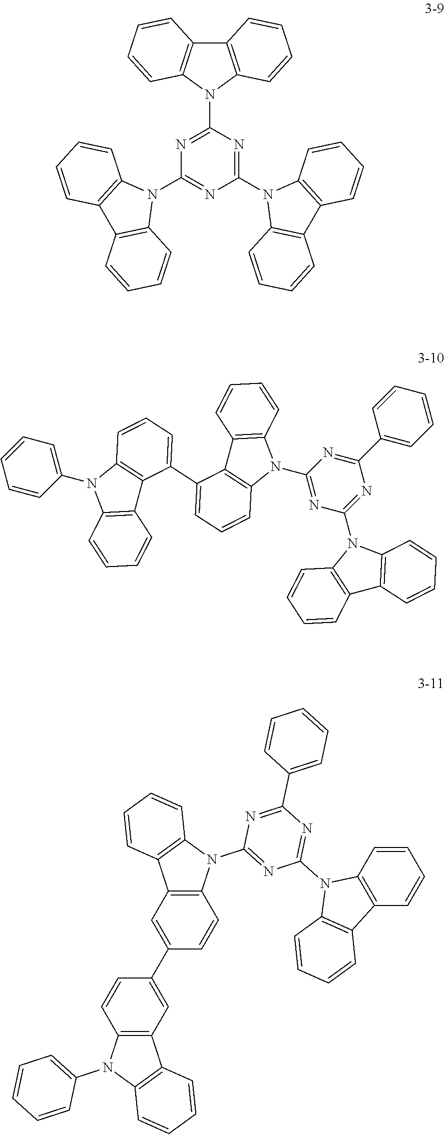

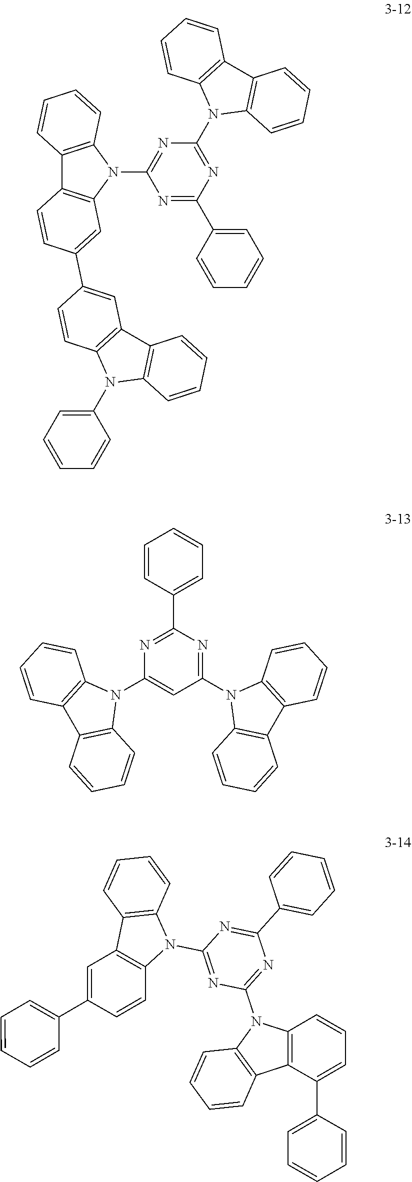

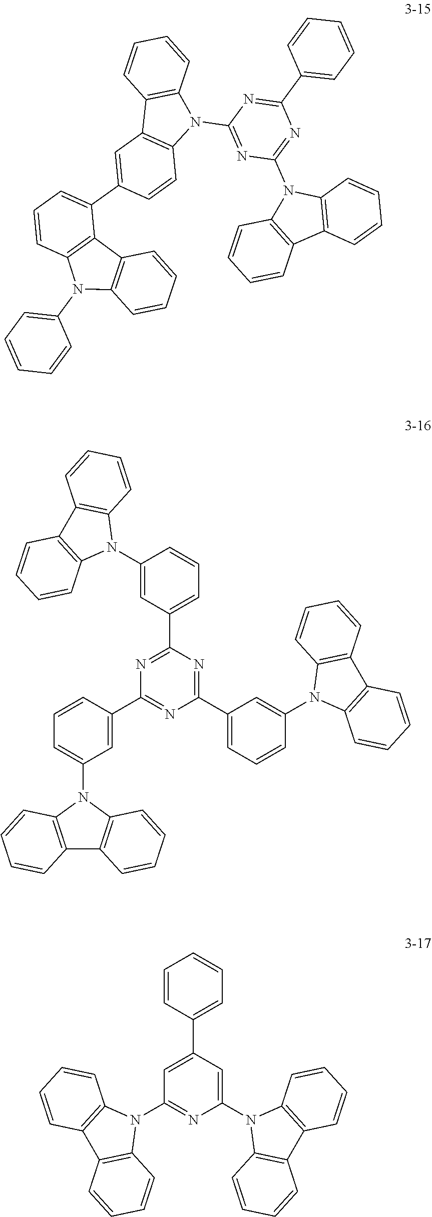

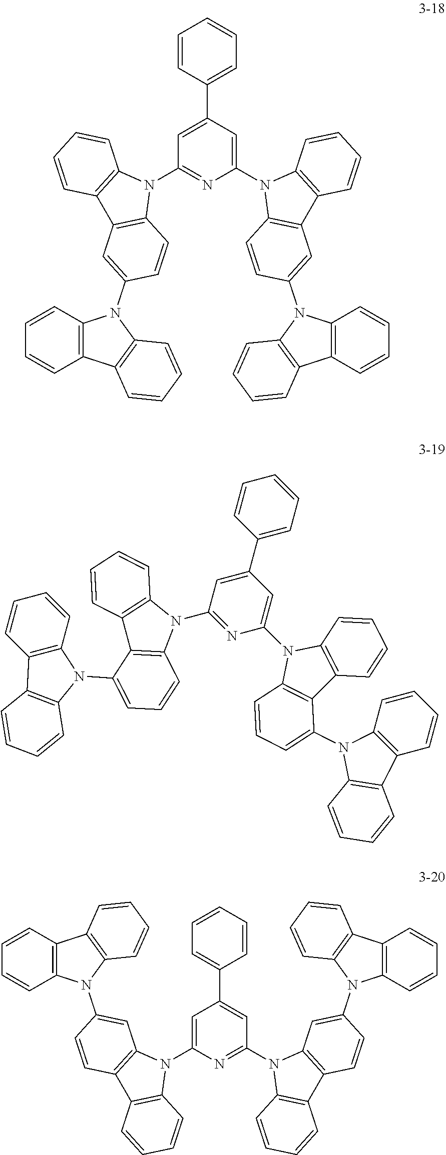

Herein, each of the aromatic hydrocarbon ring groups, the aromatic heterocyclic groups, and the linked aromatic groups may have a substituent. When these groups have a substituent, the substituent is a cyano group, an aliphatic hydrocarbon group having 1 to 10 carbon atoms, a diarylamino group having 12 to 30 carbon atoms, an alkoxy group having 1 to 10 carbon atoms, an aryloxy group having 6 to 18 carbon atoms, an alkylthio group having 1 to 10 carbon atoms, or an arylthio group having 6 to 18 carbon atoms. The number of substituents is 0 to 5, and preferably 0 to 2. When each of the aromatic hydrocarbon ring groups and the aromatic heterocyclic groups has a substituent, the number of carbon atoms of the substituent is not included in the calculation of the number of carbon atoms. However, it is preferred that the total number of carbon atoms including the number of carbon atoms of the substituent satisfy the above range. It should be noted that substituents of the ring C, the ring D, the ring E, the ring H, and the ring I are in accord with the definition of R3.

Specific examples of the above substituent include cyano, methyl, ethyl, propyl, butyl, pentyl, hexyl, heptyl, octyl, nonyl, decyl, diphenylamino, naphthylphenylamino, dinaphthylamino, dianthranilamino, diphenanthrenylamino, methoxy, ethoxy, phenol, diphenyloxy, methylthio, ethylthio, thiophenol, and diphenylthio. Preferred examples thereof include cyano, methyl, ethyl, propyl, butyl, pentyl, hexyl, heptyl, octyl, diphenylamino, naphthylphenylamino, dinaphthylamino, phenol, and thiophenol.

Herein, the term linked aromatic group refers to a group in which aromatic rings each derived from an aromatic hydrocarbon ring group or an aromatic heterocyclic group are linked via single bonds, and the aromatic rings may be linked in a linear fashion or in a branched fashion. The aromatic rings to be linked may be identical or different. When a linked aromatic group is mentioned, the linked aromatic group differs from an aromatic hydrocarbon ring group having a substituent or an aromatic heterocyclic group having a substituent.

Next, the structure of the organic EL device of the present invention will be described with reference to the drawing, but the structure of the organic EL device of the present invention is not limited thereto.

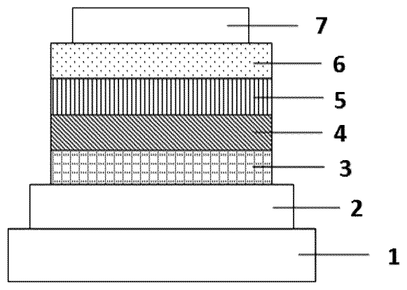

FIG. 1 shows a cross-sectional view of a structure example of a typical organic EL device used in the present invention. Reference numeral 1 denotes a substrate, reference numeral 2 denotes an anode, reference numeral 3 denotes a hole injection layer, reference numeral 4 denotes a hole transport layer, reference numeral 5 denotes a light emitting layer, reference numeral 6 denotes an electron transport layer, and reference numeral 7 denotes a cathode. The organic EL device of the present invention may have an exciton blocking layer adjacent to the light emitting layer, or may have an electron blocking layer between the light emitting layer and the hole injection layer. The exciton blocking layer may be inserted on either the cathode side or the anode side of the light emitting layer or may be inserted on both sides at the same time. The organic EL device of the present invention has the anode, the light emitting layer, and the cathode as essential layers, but preferably has a hole injection/transport layer and an electron injection/transport layer in addition to the essential layers, and further preferably has a hole blocking layer between the light emitting layer and the electron injection/transport layer. The hole injection/transport layer means either or both of the hole injection layer and the hole transport layer, and the electron injection/transport layer means either or both of the electron injection layer and electron transport layer.

It is also possible to have a structure that is the reverse of the structure shown in FIG. 1, that is, the cathode 7, the electron transport layer 6, the light emitting layer 5, the hole transport layer 4, the hole injection layer 3, and the anode 2 can be laminated on the substrate 1, in the order presented. Also, in this case, layers can be added or omitted, as necessary. In the organic EL device as described above, layers other than electrodes such as an anode and a cathode, the layers constituting a multilayer structure on a substrate, may be collectively referred to as an organic layer in some cases.

### —Substrate—

The organic EL device of the present invention is preferably supported on a substrate. The substrate is not particularly limited and may be a substrate conventionally used for organic EL devices, and for example, a substrate made of glass, transparent plastic, or quartz can be used.

### —Anode—

As the anode material in the organic EL device, a material made of a metal, alloy, or conductive compound having a high work function (4 eV or more), or a mixture thereof is preferably used. Specific examples of such an electrode material include metals such as Au, and conductive transparent materials such as CuI, indium tin oxide (ITO), SnO₂, and ZnO. An amorphous material capable of producing a transparent conductive film such as IDIXO (In₂O₃—ZnO) may also be used. As the anode, these electrode materials may be formed into a thin film by a method such as vapor deposition or sputtering, and then a pattern of a desired form may be formed by photolithography. Alternatively, when a highly precise pattern is not required (about 100 μm or more), a pattern may be formed through a mask of a desired form at the time of vapor deposition or sputtering of the above electrode materials. Alternatively, when a coatable material such as an organic conductive compound is used, a wet film forming method such as a printing method and a coating method can also be used. When light is extracted from the anode, the transmittance is desirably more than 10%, and the sheet resistance as the anode is preferably several hundred Ω/square or less. The film thickness is selected within a range of usually 10 to 1,000 nm, and preferably 10 to 200 nm, although it depends on the material.

### —Cathode—

On the other hand, a material made of a metal (referred to as an electron injection metal), alloy, or conductive compound having a low work function (4 eV or less) or a mixture thereof is used as the cathode material. Specific examples of such an electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and a rare earth metal. Among them, in terms of electron injection properties and durability against oxidation and the like, a mixture of an electron injection metal with a second metal that has a higher work function value than the electron injection metal and is stable, for example, a magnesium/silver mixture, a magnesium/aluminum mixture, a magnesium/indium mixture, an aluminum/aluminum oxide (Al₂O₃) mixture, a lithium/aluminum mixture, or aluminum is suitable. The cathode can be produced by forming a thin film from these cathode materials by a method such as vapor deposition and sputtering. The sheet resistance as the cathode is preferably several hundred $2/square or less, and the film thickness is selected within a range of usually 10 nm to 5 μm, and preferably 50 to 200 nm. To transmit the light emitted, either one of the anode and the cathode of the organic EL device is favorably transparent or translucent because light emission brightness is improved.

The above metal is formed to have a film thickness of 1 to 20 nm on the cathode, and then a conductive transparent material mentioned in the description of the anode is formed on the metal, so that a transparent or translucent cathode can be produced. By applying this process, a device in which both anode and cathode have transparency can be produced.

### —Light Emitting Layer—

The light emitting layer is a layer that emits light after holes and electrons respectively injected from the anode and the cathode are recombined to form exciton. For the light emitting layer, the emission material represented by the general formula (1) or the general formula (2) may be used alone, or the emission material may be used in combination with a host material. When the emission material is used together with the host material, the emission material serves as a light emitting dopant.

The emission material represented by the general formula (1) or the general formula (2) may also be used together with a fluorescence material other than those represented by the general formula (1) or the general formula (2). When the emission material represented by the general formula (1) or the general formula (2) is used together with the fluorescence material, the emission material may be further used together with a host material. When the emission material represented by the general formula (1) or the general formula (2) is used with a fluorescence material, the fluorescence material serves as a light emitting dopant.

When the emission material represented by the general formula (1) or the general formula (2) is contained as a light emitting dopant in a light emitting layer, the content of the light emitting dopant is suitably 0.1 to 10 wt %, and preferably 0.1 to 5 wt %. In this case, when a light emitting layer contains the above first host selected from compounds of the general formula (5) and the above second host selected from compounds of the general formula (6) as host materials, the total content in the light emitting layer is suitably 99.9 to 90 wt %, and preferably 99.9 to 95 wt %.

The host material in the light emitting layer can be a known host material used for a phosphorescent device or a fluorescent device, other than the host material shown above. A usable known host material is a compound having the ability to transport hole, the ability to transport electron, and a high glass transition temperature, and preferably has a higher triplet excited energy (T1) than the triplet excited energy (T1) of the emission material represented by the general formula (1) or the general formula (2). A TADF-active compound may also be used as the host material, and the TADF-active compound preferably has a difference between the singlet excited energy (S1) determined by measuring the emission spectrum and the triplet excited energy (T1) determined by measuring the phosphorescence spectrum (ΔEST=S1−T1, that is, ΔEST for found values), of 0.20 eV or less.

In determining ΔEST for found values, S1 and T1 are determined as follows.

A sample compound (thermally activated delayed fluorescence material) is deposited on a quartz substrate by a vacuum deposition method under conditions of a degree of vacuum of 10⁻⁴ Pa or less to form a deposition film having a thickness of 100 nm. For S1, the emission spectrum of this deposition film is measured, a tangent is drawn to the rise of the emission spectrum on the short-wavelength side, and the wavelength value λedge [nm] of the point of intersection of the tangent and the horizontal axis is substituted into the following equation (i) to calculate S1.

$$S 1 [ eV ] = 1239 \text{.85} / λedge \qquad ( i )$$

For T1, on the other hand, the phosphorescence spectrum of the above deposition film is measured, a tangent is drawn to the rise of the phosphorescence spectrum on the short-wavelength side, and the wavelength value λedge [nm] of the point of intersection of the tangent and the horizontal axis is substituted into the following equation (ii) to calculate T1.

$$T 1 [ eV ] = 1239 \text{.85} / λedge \qquad ( ii )$$

Such host materials are known in a large number of Patent Literatures and the like, and hence may be selected from them. Specific examples of the host material include, but are not particularly limited to, various metal complexes typified by metal complexes of indole compounds, carbazole compounds, indolocarbazole compounds, pyridine compounds, pyrimidine compounds, triazine compounds, triazole compounds, oxazole compounds, oxadiazole compounds, imidazole compounds, phenylenediamine compounds, arylamine compounds, anthracene compounds, fluorenone compounds, stilbene compounds, triphenylene compounds, carborane compounds, porphyrin compounds, phthalocyanine compounds, and 8-quinolinol compounds, and metal phthalocyanine, and metal complexes of benzoxazole and benzothiazole compounds; and polymer compounds such as poly(N-vinyl carbazole) compounds, aniline-based copolymer compounds, thiophene oligomers, polythiophene compounds, polyphenylene compounds, polyphenylene vinylene compounds, and polyfluorene compounds. Preferred examples thereof include carbazole compounds, indolocarbazole compounds, pyridine compounds, pyrimidine compounds, triazine compounds, anthracene compounds, triphenylene compounds, carborane compounds, and porphyrin compounds.

Only one host may be contained or two or more hosts may be used in one light emitting layer. When two or more hosts are used, the materials represented by the general formula (5) and the general formula (6) are preferably used. When a plurality of hosts is used, each host is deposited from different deposition sources, or a plurality of hosts is premixed before vapor deposition to form a premix, whereby a plurality of hosts can be simultaneously deposited from one deposition source. Alternatively, one or more hosts and one or more emission materials are premixed to form a premix, whereby hosts and emission materials can be simultaneously deposited from one deposition source.

As the method of premixing, a method by which hosts can be mixed as uniformly as possible is desirable, and examples thereof include, but are not limited to, milling, a method of heating and melting hosts under reduced pressure or under an inert gas atmosphere such as nitrogen, and sublimation.

The host and a premix thereof may be in the form of powder, sticks, or granules. The host and a premix thereof may form an excited complex.

When a fluorescence material other than those represented by the general formula (1) or the general formula (2) is used in the light emitting layer, preferred examples of the other fluorescence material include fused polycyclic aromatic derivatives, styrylamine derivatives, fused ring amine derivatives, boron-containing compounds, pyrrole derivatives, indole derivatives, carbazole derivatives, and indolocarbazole derivatives. Among them, fused ring amine derivatives, boron-containing compounds, carbazole derivatives, and indolocarbazole derivatives are preferred. Examples of the fused ring amine derivatives include diaminepyrene derivatives, diaminochrysene derivatives, diaminoanthracene derivatives, diaminofluorenone derivatives, and diaminofluorene derivatives fused with one or more benzofuro backbones.

Examples of the boron-containing compounds include pyrromethene derivatives and triphenylborane derivatives.

Preferred examples of the fluorescence material other than those represented by the general formula (1) or the general formula (2) are not particularly limited, but specific examples thereof include the following.

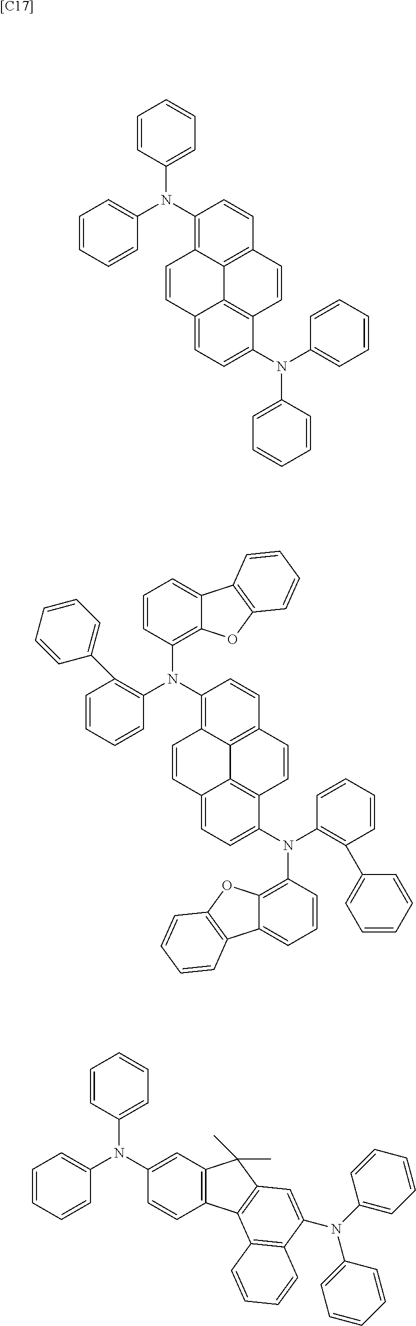

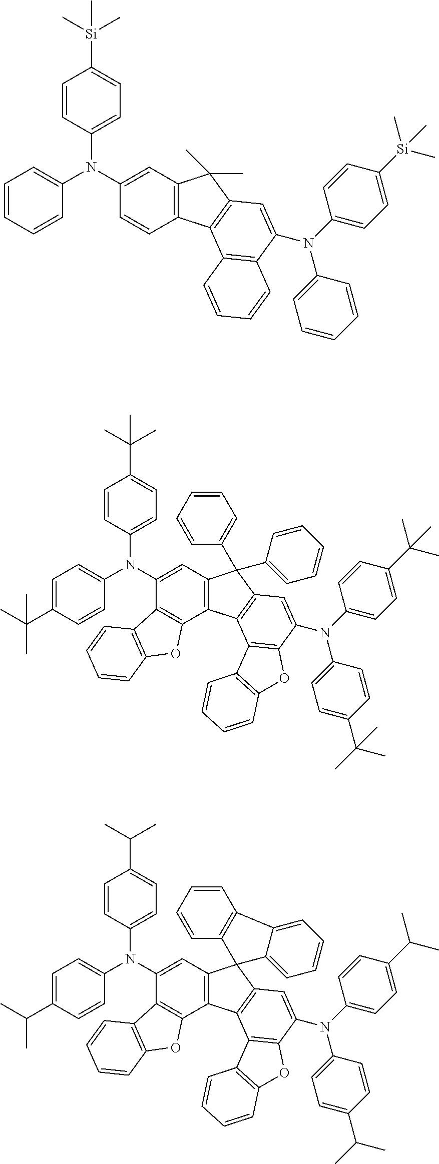

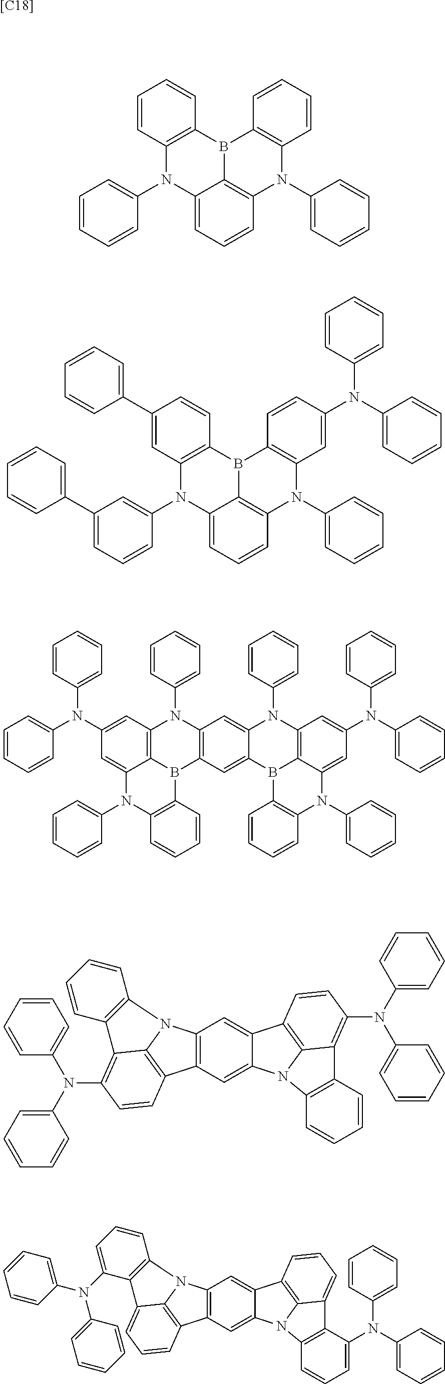

### —Injection Layer—

The injection layer refers to a layer provided between the electrode and the organic layer to reduce the driving voltage and improve the light emission brightness, and includes the hole injection layer and the electron injection layer. The injection layer may be present between the anode and the light emitting layer or the hole transport layer, as well as between the cathode and the light emitting layer or the electron transport layer. The injection layer may be provided as necessary.

### —Hole Blocking Layer—

The hole blocking layer has the function of the electron transport layer in a broad sense, is made of a hole blocking material having a very small ability to transport holes while having the function of transporting electrons, and can improve the recombination probability between the electrons and the holes in the light emitting layer by blocking the holes while transporting the electrons. For the hole blocking layer, the compound represented by the general formula (6) or a known hole blocking material can be used. The compound represented by the general formula (6) is preferred. A plurality of hole blocking materials may be used in combination.

### —Electron Blocking Layer—

The electron blocking layer has the function of the hole transport layer in a broad sense, and can improve the recombination probability between the electrons and the holes in the light emitting layer by blocking the electrons while transporting the holes. As the material for the electron blocking layer, the compound represented by the general formula (5) or a known material for the electron blocking layer can be used. The compound represented by the general formula (5) is preferred.

### —Exciton Blocking Layer—

The exciton blocking layer is a layer to block the diffusion of the excitons generated by recombination of the holes and the electrons in the light emitting layer into a charge transport layer, and insertion of this layer makes it possible to efficiently keep the excitons in the light emitting layer, so that the emission efficiency of the device can be improved. The exciton blocking layer can be inserted between two light emitting layers adjacent to each other in the device in which two or more light emitting layers are adjacent to each other. As the material for such an exciton blocking layer, a known material for the exciton blocking layer can be used.

The layer adjacent to the light emitting layer includes the hole blocking layer, the electron blocking layer, and the exciton blocking layer, and when these layers are not provided, the adjacent layer is the hole transport layer, the electron transport layer, and the like.

### —Hole Transport Layer—

The hole transport layer is made of a hole transport material having the function of transporting holes, and the hole transport layer may be provided as a single layer or a plurality of layers.

The hole transport material has any of hole injection properties, hole transport properties, or electron barrier properties, and may be either an organic material or an inorganic material. As the hole transport layer, any of conventionally known compounds may be selected and used. Examples of such a hole transport material include porphyrin derivatives, arylamine derivatives, triazole derivatives, oxadiazole derivatives, imidazole derivatives, polyarylalkane derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, aniline-based copolymers, and conductive polymer oligomers, particularly, thiophene oligomers. Porphyrin derivatives, arylamine derivatives, and styrylamine derivatives are preferably used, and arylamine derivatives are more preferably used.

### —Electron Transport Layer—

The electron transport layer is made of a material having the function of transporting electrons, and the electron transport layer may be provided as a single layer or a plurality of layers.

The electron transport material (may also serve as the hole blocking material) has the function of transmitting electrons injected from the cathode to the light emitting layer. As the electron transport layer, any of conventionally known compounds may be selected and used, and examples thereof include polycyclic aromatic derivatives such as naphthalene, anthracene, and phenanthroline, tris(8-quinolinolato) aluminum (III) derivatives, phosphine oxide derivatives, nitro-substituted fluorene derivatives, diphenylquinone derivatives, thiopyran dioxide derivatives, carbodiimide derivatives, fluorenylidene f methane derivatives, anthraquinodimethane and anthrone derivatives, bipyridine derivatives, quinoline derivatives, oxadiazole derivatives, benzimidazole derivatives, benzothiazole derivatives, and indolocarbazole derivatives. Further, polymer materials in which these materials are introduced in the polymer chain or these materials constitute the main chain of the polymer can also be used.

When the organic EL device of the present invention is produced, the film formation method for each layer is not particularly limited, and the layers may be produced by either a dry process or a wet process.

### EXAMPLES

Hereinafter, the present invention will be described in further detail with reference to Examples, but the present invention is not limited to these Examples.

The compounds used in Examples and Comparative Examples are shown below.

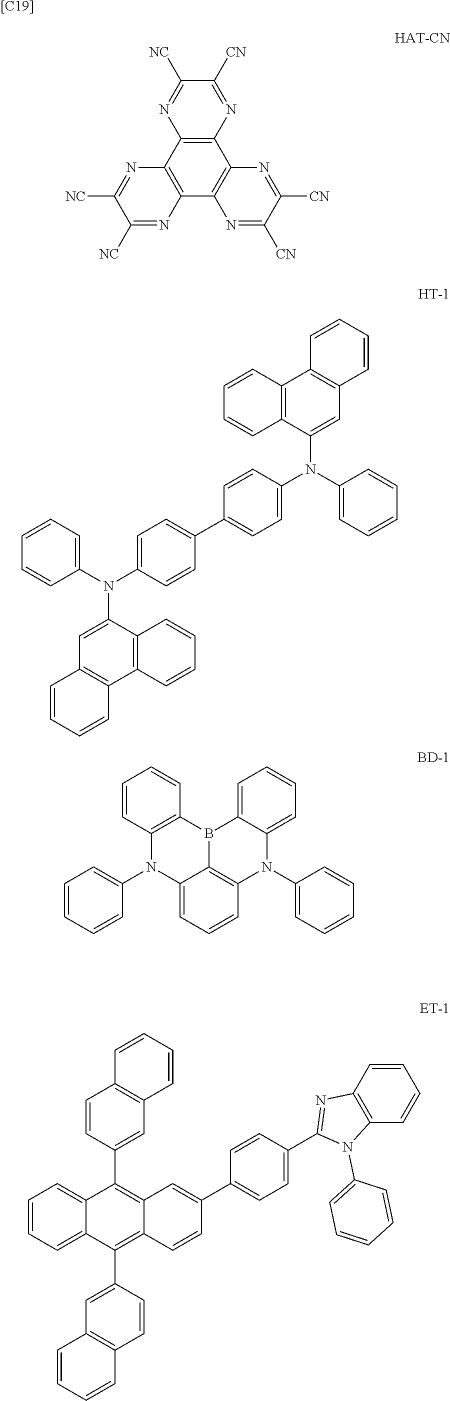

### Synthesis Example 1

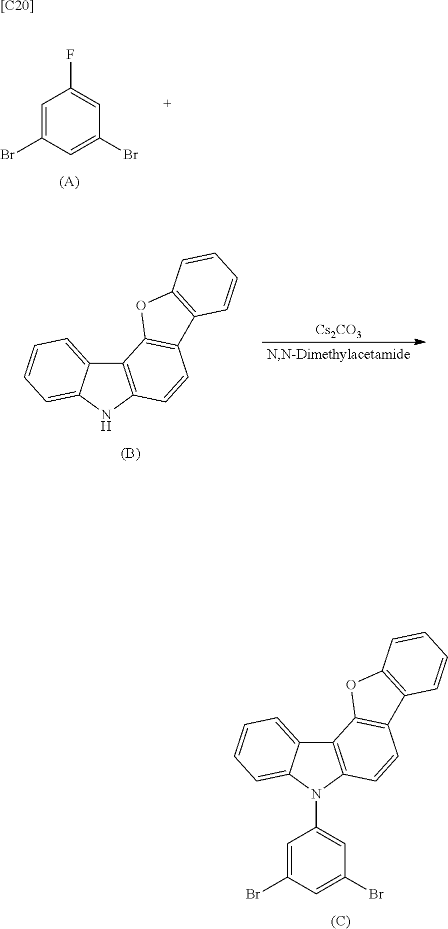

As shown in the above reaction scheme. 10.9 g of a starting material (A). 10.0 g of a starting material (B). 31.8 g of cesium carbonate, and 78 ml of N,N-dimethylacetamide were put in a three-necked flask under a nitrogen atmosphere and stirred at 160° C. for 4.5 hours. After the reaction solution was cooled to room temperature, the reaction solution was filtered, and the filtrate was put in a flask containing 500 ml of water, and stirred for 30 minutes. The precipitated solid was collected by filtering, and the collected product was then put in a flask containing 150 ml of isopropyl alcohol, and heated for 1 hour while stirred. After cooling to room temperature, the precipitated solid was collected by filtering, and the resulting solid was vacuum-dried to yield 17.0 g of an intermediate (C) (yield: 89%). APCI-TOFMS m/z 492 [M+1]⁺

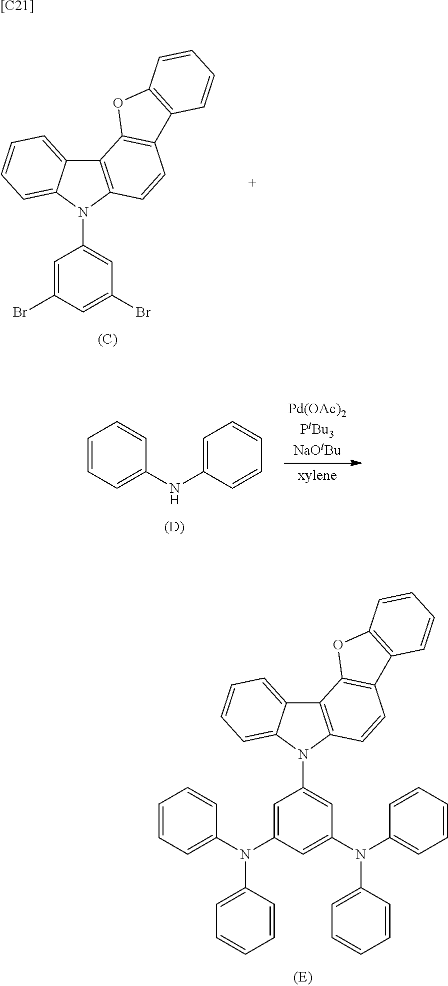

Then, 10.0 g of the intermediate (C) obtained above, 8.3 g of a starting material (D), 0.46 g of palladium acetate, 9.8 g of sodium t-butoxide, 0.8 g of tri-t-butylphosphine, and 200 ml of xylene were put in a three-necked flask under a nitrogen atmosphere and stirred at 80° C. for 2 hours. After the reaction solution was cooled to room temperature, the reaction solution was subjected to liquid separation with toluene and water, and the organic layer was concentrated. The resulting solid and 150 ml of tetrahydrofuran were put in an eggplant flask, heated for 1 hour while stirred, and then cooled to room temperature, and the solid was collected by filtering. The resulting solid was dried under reduced pressure to yield 11.5 g of an intermediate (E) (yield: 85%).

APCI-TOFMS m/z 668 [M+1]⁺

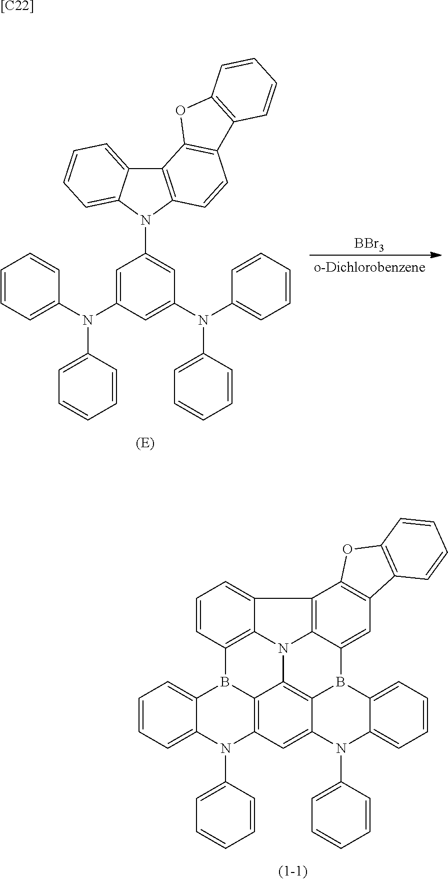

Under a nitrogen atmosphere, 2.08 g of the intermediate (E) obtained above and 30 ml of anhydrous ortho-dichlorobenzene were added. At room temperature, 25.0 g of boron tribromide was added in small amounts, and thereafter the resultant was stirred at 170° C. for 20 hours. After the reaction, the temperature was returned to room temperature, and water was added in small amounts. The reaction solution was subjected to liquid separation with chloroform and water, and the organic layer was concentrated. The concentrate was purified by silica gel column chromatography. The resulting solid was collected by filtering, and the collected product was then put in a flask containing 50 ml of toluene, and the resultant was heated for 1 hour while stirred. After cooling to room temperature, the precipitated solid was collected by filtering, and the resulting solid was dried under reduced pressure to yield 0.47 g of a compound (1-1) (yield: 22%).

APCI-TOFMS m/z 684 [M+1]⁺

S1 and T1 of the compound (1-1) and BD-1 were determined.

The compound (2-30), which has been shown as a specific example, as the host and the compound (1-1) as the light emitting dopant were co-deposited from different deposition sources on a quartz substrate by a vacuum deposition method under conditions of a degree of vacuum of 10⁻⁴ Pa or less to form a deposition film having a thickness of 100 nm. At this time, they were co-deposited under deposition conditions such that the concentration of the compound (1-1) was 2% by mass. For S1, the emission spectrum of this deposition film was measured, a tangent was drawn to the rise of the emission spectrum on the short-wavelength side, and the wavelength value λedge [nm] of the point of intersection of the tangent and the horizontal axis was substituted into the following equation (i) to calculate S1.

$$S 1 [ eV ] = 1239 \text{.85} / λedge \qquad ( i )$$

For T1, the phosphorescence spectrum of the above deposition film was measured, a tangent was drawn to the rise of the phosphorescence spectrum on the short-wavelength side, and the wavelength value λedge [nm] of the point of intersection of the tangent and the horizontal axis was substituted into the following equation (ii) to calculate T1.

$$T 1 [ eV ] = 1239 \text{.85} / λedge \qquad ( ii )$$

S1 and T1 of BD-1 were determined in the same manner, except that the compound (1-1) was replaced with BD-1.

TABLE 1

| Compound | S1[eV] | T1[eV] | S1-T1[eV] |
|---|---|---|---|
| 1-1 | 2.68 | 2.54 | 0.14 |
| BD-1 | 2.79 | 2.61 | 0.18 |

### Example 1

Thin film shown below were stacked on the glass substrate on which an anode made of ITO having a film thickness of 70 nm was formed, by a vacuum deposition method at a degree of vacuum of 4.0×10⁻⁵ Pa. First, the previously presented HAT-CN was formed on ITO to a thickness of 10 nm as a hole injection layer, and then the HT-1 was formed to a thickness of 25 nm as a hole transport layer. Then, the compound (2-30) shown as a specific example was formed to a thickness of 5 nm as an electron blocking layer. Then, the same compound (2-30) as the first host, the compound (3-3) as the second host, and the compound (1-1) in the exemplified compounds previously presented as specific examples of the general formula (1) or the general formula (2), as the dopant, were co-deposited from different deposition sources to form a light emitting layer having a thickness of 30 nm. At this time, they were co-deposited under deposition conditions such that the concentration of the compound (2-30) was 49% by mass, the concentration of the compound (3-3) was 49% by mass, and the concentration of the compound (1-1) was 2% by mass. Then, the compound (3-3) was formed to a thickness of 5 nm as a hole blocking layer. Then, ET-1 was formed to a thickness of 40 nm as an electron transport layer. Further, lithium fluoride (LiF) was formed on the electron transport layer to a thickness of 1 nm as an electron injection layer. Finally, aluminum (Al) was formed on the electron injection layer to a thickness of 70 nm as a cathode, whereby an organic EL device according to Example 1 was produced.

### Comparative Example 1

Each organic EL device was produced in the same manner as in Example 1, except that BD-1 was used as the dopant.

The maximum emission wavelength of the emission spectrum, external quantum efficiency, and lifetime of each organic EL device produced are shown in Table 2. The maximum emission wavelength and the external quantum efficiency were values at a driving current density of 2.5 mA/cm² and were initial characteristics. The time taken for the luminance to reduce to 80% of the initial luminance when the driving current density was 2.5 mA/cm² was measured as the lifetime.

TABLE 2

| | Maximum emission | External quantum | |
|---|---|---|---|
| | wavelength | efficiency | Lifetime |
| | (nm) | (%) | (h) |
| Example 1 | 490 | 11.6 | 33 |
| Comp. Example 1 | 461 | 9.6 | 17 |

From the comparison of the data of Example 1 with Comparative Example 1 as shown in Table 2, the organic EL device including, as a light emitting dopant, the emission material represented by the general formula (1) or the general formula (2), in which a specific backbone was combined with a boron atom, showed excellent results in efficiency and lifetime and showed excellent results particularly in lifetime characteristics. It is considered that the reason for this is as follows: the use of a backbone having a specific structure expanded conjugation, and improved the stability against oxidation and reduction, and lifetime characteristics.

### Example 2

S1 and T1 can be determined not only by actual measurement as described above, but also by theoretical calculation using a molecular orbital method program as shown below. In the case of small S1−T1 as determined by theoretical calculation, the reverse intersystem crossing more frequently occurs to allow efficient use of triplet excitons for emission, and thus high emission efficiency is expected to be given.

For 1-1, 1-3, 1-67, and 1-70, which were emission materials represented by the general formula (1) or the general formula (2), structural optimization calculation was performed with the molecular orbital method program Gaussian 16 at a TDA-PBE0/6-31G* level on the basis of the density functional theory (DFT) to calculate S1 (theo), T1 (theo), and S1−T1 (theo). The results are shown in Table 3. S1 (theo), T1 (theo), and S1−T1 (theo) were determined for BD-1 as Comparative Example in the same manner, and the results are shown in Table 3.

TABLE 3

| | S1(theo) | T1(theo) | S1-T1(theo) |
|---|---|---|---|
| Compound | [eV] | [eV] | [eV] |
| 1-1 | 2.92 | 2.57 | 0.35 |
| 1-3 | 2.95 | 2.51 | 0.44 |
| 1-67 | 3.06 | 2.64 | 0.42 |
| 1-70 | 3.04 | 2.62 | 0.43 |
| BD-1 | 3.22 | 2.67 | 0.55 |

As demonstrated in Table 3, 1-1, 1-3, 1-67, and 1-70, which were emission materials represented by the general formula (1) or the general formula (2), showed smaller S1−T1 (theo) than BD-1, and as a result the reverse intersystem crossing more frequently occurs than in BD-1 to allow efficient use of triplet excitons for emission, and thus high emission efficiency is expected to be given.

For the emission material of the present invention represented by the general formula (1) or the general formula (2), S1−T1 (theo)<0.55 eV is desired, and S1−T1 (theo)<0.45 eV is more preferred.

### REFERENCE SIGNS LIST

1 substrate, 2 anode, 3 hole injection layer, 4 hole transport layer, 5 light emitting layer, 6 electron transport layer, 7 cathode.

1. An emission material represented by the following general formula (1) or general formula (2): 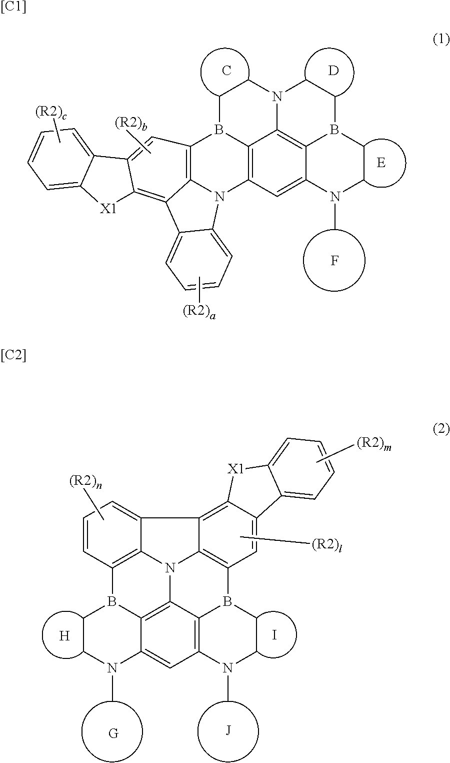
wherein a ring C, a ring D, a ring E, a ring H, and a ring I each independently represent a substituted or unsubstituted aromatic hydrocarbon ring having 6 to 24 carbon atoms, or a substituted or unsubstituted aromatic heterocyclic ring having 3 to 18 carbon atoms;
a ring F, a ring G, and a ring J each independently represent a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings;
a hydrogen atom in the general formulas (1) and (2) is optionally replaced with a deuterium atom;
each X1 independently represents N—R1, O, or S, wherein R¹ represents a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings;
each R2 independently represents an aliphatic hydrocarbon group having 1 to 6 carbon atoms, a substituted or unsubstituted aromatic hydrocarbon ring group having 6 to 24 carbon atoms, a substituted or unsubstituted aromatic heterocyclic group having 3 to 18 carbon atoms, or a substituted or unsubstituted linked aromatic group formed by linking 2 to 8 these aromatic rings; a, b, c, l, m, and n each represent the number of substitutions; a, c, and m each independently represent an integer of 0 to 4; n represents an integer of 0 to 3; b and 1 each independently represent an integer of 0 to 1;
each pair of a pair of the ring C and the ring D and a pair of the ring E and the ring F in the general formula (1) optionally together forms a ring via a direct bond or a linking group; and each pair of a pair of the ring H and the ring G and a pair of the ring I and the ring J in the general formula (2) optionally together forms a ring via a direct bond or a linking group.

2. The emission material according to claim 1, wherein the general formula (1) is represented by the following general formula (3), and the general formula (2) is represented by the following general formula (4): 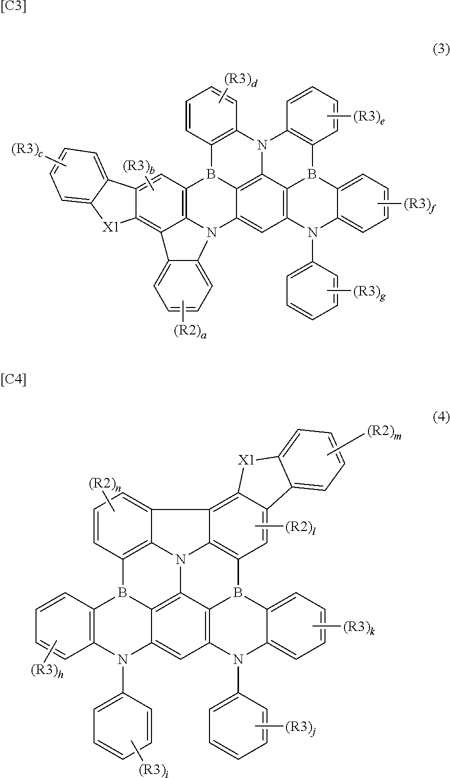
wherein X1, R2, a, c, m, n, b, and I have the same meanings as described for the general formula (1) or (2); each R3 independently represents an aliphatic hydrocarbon group having 1 to 6 carbon atoms, a substituted or unsubstituted aromatic hydrocarbon ring group having 6 to 24 carbon atoms, or a substituted or unsubstituted aromatic heterocyclic group having 3 to 18 carbon atoms; d, e, f, g, h, i, j, and k each represents the number of substitutions; g, i, and j each independently represent an integer of 0 to 5; and d, e, f, h, and k each independently represent an integer of 0 to 4.

3. An organic electroluminescent device comprising one or more light emitting layers between an anode and a cathode opposite to each other, wherein at least one of the light emitting layers contains the emission material according to claim 1.

4. The organic electroluminescent device according to claim 3 comprising one or more light emitting layers between an anode and a cathode opposite to each other, wherein at least one of the light emitting layers contains a first host selected from compounds represented by the following general formula (5) and a second host selected from compounds represented by the following general formula (6): 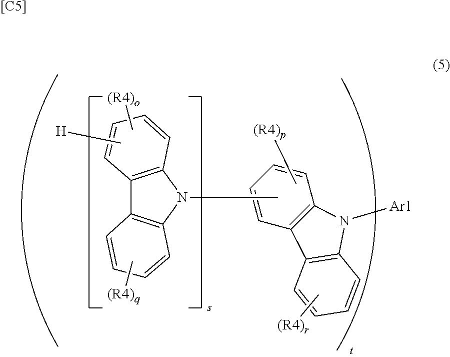
wherein Ar1 represents a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings; each R4 independently represents an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms; o, p, q, and r each represent the number of substitutions; q and r each independently represent an integer of 0 to 4; o and p each independently represent an integer of 0 to 3; s represents the number of repetitions and an integer of 1 to 4; t represents the number of substitutions and an integer of 1 or 2; and a hydrogen atom in the general formula (5) is optionally replaced with a deuterium atom, 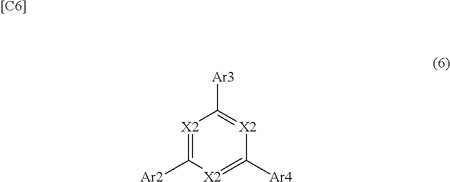
wherein each X2 independently represents N or C—R5, provided that at least one X2 represents N; Ar2, Ar3, and Ar4 each independently represent a substituted or unsubstituted aromatic hydrocarbon ring group having 6 to 18 carbon atoms, a substituted or unsubstituted aromatic heterocyclic group having 3 to 18 carbon atoms, or a substituted or unsubstituted linked aromatic group formed by linking 2 to 8 these aromatic rings; each R5 independently represents hydrogen, deuterium, an aliphatic hydrocarbon group having 1 to 6 carbon atoms, a substituted or unsubstituted aromatic hydrocarbon ring group having 6 to 18 carbon atoms, or a substituted or unsubstituted aromatic heterocyclic group having 3 to 18 carbon atoms; and a hydrogen atom in the general formula (6) is optionally replaced with a deuterium atom.

5. The organic electroluminescent device according to claim 3, wherein the emission material represented by the general formula (1) or (2) has a difference between singlet excited energy (S1) determined by measuring an emission spectrum and triplet excited energy (T1) determined by measuring a phosphorescence spectrum (ΔEST), of 0.20 eV or less.

6. The organic electroluminescent device according to claim 4, comprising a light emitting layer containing 0.1 to 10 wt % of the emission material represented by the general formula (1) or (2) as a dopant, and 99.9 to 90 wt % of the first host represented by the general formula (5) and the second host represented by the general formula (6) in total.

7. The organic electroluminescent device according to claim 4, wherein the emission material represented by the general formula (1) or (2) has a difference between singlet excited energy (S1) determined by measuring an emission spectrum and triplet excited energy (T1) determined by measuring a phosphorescence spectrum (ΔEST), of 0.20 eV or less.
